(19) United States
(12) Patent Application Publication
(10) Pub. No.: US 2026/0354076 A1
(43) Pub. Date: Nov. 5, 2026

(54) Method for producing a III-V substrate, particularly GaAs and InP

(71) Applicant: Freiberger Compound Materials GmbH, Freiberg (DE)

(72) Inventors: Wolfram FLIEGEL, Dresden (DE); Max SCHEFFER-CZYGAN, Chemnitz (DE); Denny DEUTSCH, Freital (DE); Berndt WEINERT, Freiberg (DE); Marc DIETRICH, Großschirma (DE); Stefan EICHLER, Dresden (DE)

(21) Appl. No.: 19/125,332

(22) PCT Filed: Oct. 15, 2024
(86) PCT No.: PCT/EP2024/079036

§ 371 Date: Apr. 29, 2025

(30) Foreign Application Priority Data
Oct. 16, 2023 (DE) 102023210126.2

(51) Int. Cl. H10P 72/00; H10P 70/00

(52) U.S. Cl. CPC H10P 72/0408; H10P 70/18

(57) ABSTRACT

The present invention comprises a method for the drying of a wafer W, W1, W2 that is submerged in a bath 1, as well as an undoped and a doped wafer W, W 1, W 2 according to the present invention, as well as a device for drying of wafers W, W1, W2.

Therein, care is taken to ensure that the travel distance of the wafers W, W1, W2 is kept as short as possible, few residual droplets remain adhering to the wafer W, W1, W2, and the wafer W, W1, W2 thus reveals an oxide surface that is as homogeneous as possible, and the number/area of defect areas resulting from adhering residual droplets after the Marangoni drying can be minimized. Accordingly, little or, ideally, no contact between wafer W and rack 3; 31, 32/guiding device 3a, 3a′; 3b, 3b′; 3c, 3c′ is given when crossing the water surface. In addition, the continuous overflow can be maintained, i.e., preferably, there is no lowering of the water level when the wafers W (and ideally the racks 3; 31, 32 as well) are being dried.

The present invention relates to a method for producing improved surfaces of III-V substrates, and for producing III-V substrates per se, wherein the materials GaAs and InP are of particular relevance.

### BACKGROUND OF THE INVENTION

III-V substrates, particularly gallium arsenide substrates, and particularly wafers thereof, are used in various applications and have an increasingly significant economic importance. Examples of these include high-frequency amplifiers and switches, as well as light-emitting components such as semiconductor lasers and diodes. Particularly, transistors and diodes are primarily made from single-crystalline chemical compounds that are grown epitaxially. Growth parameters may be adjusted to the crystal lattice, in particular. The lattice-matched epitaxy ensures high quality and low defect densities. However, the quality not only depends on the conditions during the epitaxy but also on the properties of the substrate itself, which frequently affect the quality. In case of gallium arsenide, in particular, the problem of a fast formation of an oxide layer at the surface of the substrate occurs, which, when no proper surface treatment takes place, may form with an inhomogeneous composition (gallium oxide and arsenic oxide of varying oxidation states). The thermal properties of differently composed oxides are partially very different.

However, for subsequent epitaxy processes it needs to be ensured that the oxide layer can be easily removed by thermal treatment.

For example, document EP 2 629 319 A1 is known in the state-of-the-art which teaches that gallium arsenide, in particular, has physical and chemical surface properties that are significantly different from other semiconductors, such as silicon. As the surface of a gallium arsenide wafer contains gallium atoms and arsenic atoms that show different chemical properties (also in terms of reactivity), the surface reactivity is a special phenomenon here: The surface layer may be composed of gallium dioxide (Ga₂O₃), arsenic trioxide (As₂O₃), arsenic pentoxide (As₂O₅) and to a small extent of elemental arsenic. When gallium arsenide is grown, the surface needs to be manufactured using a specific method that is disclosed by this document: treatment with ammonia solution, hydrogen peroxide and water, rinsing of the wafer with deionized water, treatment of the wafer using an oxidizing agent, repeated rinsing of the wafer using deionized water, treatment of the wafer using diluted acid solution or diluted alkaline solution, re-rinsing of the wafer using deionized water, and, finally, drying of the wafer.

During the surface treatment of gallium arsenide, foreign particles may very easily adhere, which are disadvantageous for subsequent epitaxy processes, as they would lead to an increased number of defects. Further state-of-the-art literature (Klaus Wolke et al., “Marangoni wafer drying avoids disadvantages”, Solid State Technology, August 1996) reports on the Marangoni drying method of silicon wafers. Herein, it is disclosed that Marangoni drying is based on a physical force that moves liquids off surfaces with varying surface tension, thereby establishing an equilibrium. Small amounts of water with a low surface tension (that contain absorbed isopropanol) move into a bulk liquid that has a normal surface tension. For example, an isopropanol-nitrogen atmosphere having a lower surface tension may be used. In contrast, normal water has a higher surface tension. Water tends to form a positive meniscus when solids cross the gas-liquid interface, e.g., upon removal of the wafers from a bath. The presence of water-soluble materials, e.g., isopropanol, in the atmosphere leads to an increased concentration of the solvent in the meniscus compared to the rest of the bath. When a wafer is pulled out of the bath, the water in the meniscus is drawn down into the bulk liquid, resulting in a completely dry wafer surface, with no adhering water droplets on the wafer surface that could cause so-called water spots.

The Marangoni effect thus arises from a difference in interfacial tension. A fluid, in this case water, then flows along the wafer into the direction of the higher tension, which, in turn, leads to the removal of water from the wafer and enables drying of the wafer without residues.

The Marangoni drying of semiconductor wafers relies on the spatial separation of the wafers and ultrapure water under the impact of a gradient in surface tension in the interfacial layer of ultrapure water in contact with the wafer. The spatial separation may be realized by lifting the wafer out of an ultrapure water-filled bath of a wet processing unit for semiconductor wafers or by lowering the water level.

In document WO 2014/124980 A2, a production method for GaAs substrates and a gallium arsenide substrate produced therewith are disclosed, wherein the method includes Marangoni drying. It has been recognized that specific surface cleaning steps (acid cleaning, alkaline cleaning, contacting with an oxidizing agent) in combination with the Marangoni drying contribute to a significantly improved homogeneity of the oxide surface compared to a method that does not involve a drying method based on subsequent Marangoni drying after the cleaning steps.

Thereby, the number of defects and the defect area on the surface of the wafer could be significantly reduced compared to a method that does not include Marangoni drying. Herein, those areas are regarded as defect areas, whose measurement signal obtained via Candela ellipsometry lies outside defined thresholds. This is a standard function of the Candela ellipsometer and directly output by the device.

Marangoni drying is particularly suitable for the drying of semiconductor wafers after a wet-chemical cleaning. Therein, the drying preferably occurs uniformly across the entire surface and is largely free of residues. Prior to the beginning of the drying, the semiconductor wafers are typically arranged perpendicular to a process carrier that is arranged in an ultrapure water-filled process bath. Frequently, said bath concerns the ultimate bath of a so-called wet bench: a series of sequentially aligned baths filled with liquid, in which the wafers are subjected to the chemical and rinsing steps required for cleaning.

In the highly productive semiconductor industry, the process carriers with the wafers are typically moved from one bath to another bath by an automatic handling system after completion of each of the intended process time. Drying according to the Marangoni method exists in various configurations. However, common underlying principles exist for all Marangoni methods: A liquid that reduces the surface tension of the water inside the bath is added onto the water surface. Typically, this concerns isopropyl alcohol (isopropanol, abbreviated as IPA).

The actual drying proceeds through the slow spatial separation of the wafers and the upper water layer that shows a reduced surface tension due to the presence of isopropanol. This spatial separation may occur in different ways, such as lifting the wafers out of the water, lowering the water level, or a combination of both. For a good drying result, the relative removal speed of wafers and water level lies in the range of, e.g., 1 mm/s.

During the Marangoni drying, water droplets, so-called residual droplets, may adhere to the necessarily remaining contact points between wafer and clamping device upon their crossing of the phase boundary, which may lead to a chemically altered oxide layer that negatively affects the crystalline quality of the epitaxial layers deposited onto the wafers during device manufacturing. Water drying in a delayed and uncontrolled manner may cause damage to the wafer surface.

During the further processing of the semiconductor wafers to electronic or optical devices, extremely surface-sensitive coating processes may be applied within the framework of the so-called planar technology, in which thin semiconductor layers are deposited in single-crystalline form onto the surface of the wafers. This process, that is referred to as epitaxy, imposes extremely high quality requirements on the surface of the semiconductor wafers.

So-called III-V semiconductors, in particular GaAs and InP, show distinguishing features over silicon wafers, for example, in terms of an altered surface tension, a significantly increased surface reactivity and a more complex chemical composition of the oxide layer. Additionally, the preferred further processing of these wafers through single-crystal coating with other III-V materials imposes higher requirements regarding lateral homogeneity of the composition of the oxide layer as compared to silicon wafers.

Also, residual droplets may more easily form during Marangoni drying in case of III-V semiconductor wafers and have a more negative consequence on subsequent processes in the context of device manufacturing.

In dry state, the surface of certain semiconductor wafers (in particular, GaAs and InP) is always covered with a thin, non-crystalline oxide layer. This layer typically ranges between 1 to 2 nanometers in thickness (for InP, layer thicknesses below 1 nm may be possible) and hence only consists of a few atomic layers. During the wet chemical cleaning and rinsing processes, the oxide layer undergoes complex changes, is removed, reformed, or altered in its composition. The oxide layer formed on the wafer surface after the cleaning, rinsing, and drying processes has a passivating effect, and is thermally removed from the wafer surface immediately before the epitaxial coating in certain applications.

However, an ideal and laterally homogeneous composition of the oxide layer is an important requirement, so that the remaining starting surface after the thermal desorption of the oxide layer enables a best possible crystallographic coupling of the layers to be deposited across the entire surface for the epitaxy, thereby facilitating an ideal current flow in the devices subsequently manufactured from these epitaxial layers.

Remaining, delayed and uncontrolled drying water droplets after the Marangoni drying cause an unfavorably altered composition of the oxide layer with partially crystalline areas in the corresponding areas at the wafer surface. In the areas of the wafer surface that are thus disturbed, incomplete desorption of the surface oxide may occur during desorption before the epitaxy process, resulting in a roughening of the wafer surface. As a result, the single-crystalline growth of the functional layers is disturbed, leading to the development of crystal defects such as dislocations, grain boundaries and twin lamellae. This ultimately disrupts the current flow in the devices manufactured from the epitaxially grown material and can potentially lead to yield losses.

In principle, there are several different possibilities for drying a wafer after the surface treatment and for lifting a wafer out of the bath for the Marangoni drying method.

In an embodiment, a wafer or a group of wafers is held by a rack (holding arrangement with rods) in the water bath. In this first embodiment, the rinsing water (usually after the cleaning step with deionized water) is drained; in the context of the present invention, however, it has been found that residual droplets are frequently formed at the contact points of the wafer or the wafers, at which these are fixed to the rack and at which homogeneous drying is disturbed. Accordingly, the quality of the surface layer of the oxide layer at the surface of the wafer is locally reduced, the surface oxide layer becomes inhomogeneous, which leads to reduced quality in later grown epitaxial layers.

In the second embodiment, the wafers are lifted out of the water bath by a wedge that is pushed vertically upward, the wafers being temporarily held by said wedge as well as by wafer holders, e.g., located in the lid of the dryer. In the context of the present invention, it has been found that, in this embodiment, residual droplets may be prevented at multiple contact points.

Yet, a droplet is usually present around the wedge when passing through the water surface. Further, the drying is restricted to certain wafer diameters due to the fixed arrangement of the wafer holder in the lid of the dryer.

Further methods for lifting a wafer or a group of wafers out of a cleaning bath are disclosed in document WO 2001/078112 A1. Herein, two opposing gripping elements with receiving slots facing one another are present, where said gripper arms can grip wafers when these are lifted out of the water surface by a wedge.

Further, document DE 199 243 02 A1 discloses a method for drying substrates according to the Marangoni effect. Herein, during the lifting of the substrate, at least one additional fluid is delivered laterally to the substrate and onto the treatment fluid and is directed towards regions between the substrates.

Further, document DE 10 359 320 A1 teaches a method for drying substrates, wherein substrates are lifted out of the bath containing the treatment fluid and a fluid that reduces the surface tension of the treatment liquid is applied to the treatment liquid through at least two opposing feed devices facing each other, resulting in the supply of the fluid that reduces the surface tension of the treatment liquid being controlled in such a way that the opposing feed devices are alternately supplied with fluid.

The methods known from the prior art are often complex in terms of apparatus; they are still associated with the disadvantage, or even intentionally accept, that residual droplets remain when lifting the wafers out of the treatment fluid, which lead to the formation of “spots” on the wafer, which may, in turn, disturb subsequent epitaxial growth of thicker crystal layers. In the context of the present invention, “spots” refer to surface defects which emerged from residual droplets adhering to the wafer and which can be detected by means of Candela surface ellipsometry.

For example, “spots” relate to a chemically altered surface oxide layer composition at the wafer surface compared to areas where no such “spots” are present.

It is therefore an objective of the present invention to provide a method which is not complex in terms of apparatus and can be easily realized, with which wafers of varying sizes can be dried, and with which the formation of residual droplets during the lifting out of the wafers can be minimized or, if possible, completely avoided. The provision of III-V wafers with a very homogeneous oxide surface can be regarded as an additional objective of the present invention.

### SUMMARY OF THE INVENTION

Said objective is solved by a method according to claim 1, a III-V wafer according to claim 14 or 16, and a device for drying wafers according to claim 18. Further beneficial embodiments of the present invention are the subject of the corresponding dependent claims.

Ellipsometry-based surface mappings, that were performed using a Candela ellipsometer, were used for the characterization of the surface properties of the corresponding wafers. Details of the corresponding measurements are explained accordingly in the description and examples.

Without limiting the invention, the following items are provided to describe the main aspects, preferred embodiments, and special features of the present invention as follows:

1. Method for drying a wafer (W) that is located inside a bath (1), by using an arrangement comprising at least one wedge (2) and a pair of first lateral guiding devices (3a, 3a′), a pair of second lateral guiding devices (3b, 3b′) and a pair of third lateral guiding devices (3c, 3c′), wherein
the pair of first lateral guiding devices (3a, 3a′) is arranged below the pair of second lateral guiding devices (3b, 3b′), and the pair of second lateral guiding devices (3b, 3b′) is arranged below the pair of third lateral guiding devices (3c, 3c′), and
wherein the method comprises the following steps:
i) Vertical upward movement of at least one of the wedges (2) until reaching the wafer at its lowest point, vertical upward movement of the pair of first lateral guiding devices (3a, 3a′) and the pair of second lateral guiding devices (3b, 3b′), wherein the wafer (W) contacts the pair of first lateral guiding devices (3a) and the pair of second lateral guiding devices (3b), wherein an upper area of the wafer (W) is lifted out of the bath (1), wherein the pair of third lateral guiding devices (3c) is not contacting the wafer;
ii) Vertical upward movement of the wedge (2) until the pair of first lateral guiding devices (3a, 3a′) and the pair of second lateral guiding devices (3b, 3b′) are not contacting the wafer (W) anymore, while still being below the liquid surface of the bath (1), wherein the pair of third lateral guiding devices (3c, 3c′) contacts the wafer above the liquid surface of the bath (1);
iii) Lifting of the wafer (W) above the liquid level of the bath (1), wherein the pair of third lateral guiding devices (3c, 3c′) contacts the wafer (W).

In an embodiment, the distance between the pair of first lateral guiding devices (3a, 3a′) from each other is smaller than the distance between the pair of second lateral guiding devices (3b, 3b′) from each other, and the distance between the pair of second lateral guiding devices (3b, 3b′) from each other is smaller than the distance between the pair of third lateral guiding devices (3c, 3c′) from each other.

2. Method for drying of a wafer (W) according to item 1, further comprising the following steps:
iv) Vertical downward movement of a wedge (2) until the wafer (W) contacts at least one of the pairs of the first lateral guiding devices (3a) and the second lateral guiding devices (3b);
v) further vertical downward movement of a wedge (2), until it no longer contacts the wafer (W);
while in parallel to the step(s) iv) and/or v), or after the step v), the liquid level of the bath (1) is lowered until the liquid level is below the wedge (2).

3. Method according to item 1 or 2, wherein the bath contains water and at least one additional surface tension-reducing substance.

4. Method according to item 3, wherein at least one additional surface tension-reducing substance is isopropanol.

5. Method according to any one of items 2 to 4, wherein the pair of first lateral guiding devices (3a, 3a′) and the pair of second lateral guiding devices (3b, 3b′) remain submerged in the bath (1) in step i), and the pair of third lateral guiding devices (3c, 3c′) does preferably not contact the wafer (W, W1, W2) in the end of step v).

6. Method according to any one of the preceding items, wherein the pair of first lateral guiding devices (3a, 3a′), the pair of second lateral guiding devices (3b, 3b') and/or the pair of third lateral guiding devices (3c, 3c′) each consist(s) of a pair of webs that are arranged in a way to contact opposing sides of the wafer (W).

7. Method according to any one of the preceding items, wherein the pair of first lateral guiding devices (3a, 3a′), the pair of second lateral guiding devices (3b, 3b') and, optionally, the pair of third lateral guiding devices (3c, 3c′) are further being held by a carrier device (3d), so that a vertical movement of the pair of first lateral guiding devices (3 a, 3a′), second lateral guiding devices (3 b, 3 b′) and, optionally, third lateral guiding devices (3c, 3c′) occurs always synchronously.

8. Method according to any one of the preceding items, wherein the pair of first lateral guiding devices (3a, 3a′) and the pair of second lateral guiding devices (3b, 3b′) remain submerged in the bath (1) in step i).

9. Method according to any one of the preceding items 2 to 8, wherein the pair of third lateral guiding devices (3c, 3c′) does not contact the wafer (W) in the end of the steps iv) and v).

10. Method according to any one of the preceding items, wherein step ii) further includes fixing of the wafers by an additional gripping device (4) that is mounted above the liquid level of the bath (1).

11. Method according to any one of the preceding items, wherein the wedge (2) contains suction devices (6), to which a vacuum is applied when the upper tip of the wedge (2) is located above the liquid level.

12. Method according to item 11, wherein the suction devices (6) represent openings in the wedge (2, 2a, 2b).

13. Method according to any one of the preceding items, wherein the wedge (2) is made from plastics, preferably from polyether ether ketone (PEEK).

14. Method according to any one of the preceding items, wherein the wedge (2) reveals a surface tension-increasing surface structure.

Said structure may be achieved via plasma treatment, for instance.

15. Method according to any one of the preceding items, wherein the pair of first lateral guiding devices (3a, 3a′), the pair of second lateral guiding devices (3b, 3b′) and the pair of third lateral guiding devices (3c, 3c′) reveals notches.

16. Method according to any one of items 1 to 15, wherein the lifting speed depends on the position of the lowest point of the wafer (W),
and lies between 0.8 to 1.2 mm/s, when the lowest point of the wafer (W) is more than 1.2 cm below the liquid level, or between 0.4 and 0.5 mm/s, when the lowest point of the wafer (W) is less than 1.2 cm below the liquid level, and at least 30 mm/s, preferably at least 40 mm/s, more preferably at least 50 mm/s, as soon as the lowest point of the wafer (W) has reached the liquid level.

17. Method according to any one of items 1 to 16, wherein the pair of first lateral guiding devices (3a, 3a′), the pair of second lateral guiding devices (3b, 3b′) and the pair of third lateral guiding devices (3c, 3c′) are mounted on a rack (3), and
the rack (3) is moved in step i), the wafer (W) is lifted above the liquid level of the bath (1) in step iii), wherein the pair of third lateral guiding devices (3c, 3c′) and the wedge (2) contact the wafer (W).

18. Method according to any one of items 1 to 16, wherein the pair of third lateral guiding devices (3c, 3c′) is positioned above the liquid level in all process steps and independently movable from the pair of first lateral guiding devices (3a, 3a′) and the pair of second lateral guiding devices (3b, 3b′), and the third lateral guiding devices (3c, 3c′) are horizontally movable relative to each other.

19. Method according to item 18, wherein the wedge (2) remains below the liquid level in all process steps.

20. Method according to item 18 or 19, wherein the distance between the points at which the third lateral guiding devices (3c, 3c′) contact the wafer is continuously reduced in step iii).

21. Method according to any one of items 18 to 20, wherein the third lateral guiding devices (3c, 3c′) are adapted to perform a horizontal movement relative to each other.

22. Method according to any one of items 18 to 21, wherein the third lateral guiding devices (3c, 3c′) are either eccentrically mounted or show an oval shape and are designed to perform a rotating motion.

23. III-V wafer (W), in which the oxide surface reveals a defect area of less than 25mm², and in which the III-V wafer (W) is semi-insulating.

Semi-insulating means for many compounds (such as, for example, GaAs) that the Fermi level lies near the center of the band gap. In case of GaAs, this may be ensured by the intrinsic point defect EL2 (arsenic-antisite on gallium site), beside a certain amount of doping with carbon (C). In case of InP, doping with iron is necessary in order to yield semi-insulating properties.

The following applies for the charge carrier concentration: At a charge carrier concentration of less than 1×10¹⁰ cm⁻³, wafers are deemed semi-insulating, at a charge carrier concentration of more than 1×10¹⁰ cm⁻³ they are deemed semiconducting. The determination of the charge carrier concentration is described in the standard “SEMI M39”.

According to the standard “SEMI M87”, the specific resistance is larger than 1×10⁵ Ωcm for semi-insulating wafers, whereas wafers with lower values than this value can be regarded as semiconducting.

24. III-V wafer (W) according to item 23, in which the oxide surface reveals a defect area of less than 15 mm², preferably less than 10 mm², more preferably less than 5 mm².

25. At least one-sided polished, dried, and semi-insulating III-V wafer (W) with an oxide layer on the entire surface, in which a surface that shows an altered surface oxide composition compared to the rest of the entire surface of the III-V wafer is less than 5 mm².

Here, a measurement was carried out through Candela surface ellipsometry using the measurement channel QAbsPhase.

26. III-V wafer (W) according to item 23, 24 or 25, in which the III-element is selected from Ga and In, and the V-element is selected from As and P.

27. III-V wafer (W) according to item 26, where the III-V wafer is composed of GaAs or InP, in which GaAs and InP may be undoped or doped with carbon (C) and doped with iron (Fe), respectively.

28. III-V wafer (W) according to any one of items 23 to 27, in which the specific resistance lies between 1×10⁸ and 8×10⁸ Ωcm.

29. III-V wafer (W), in which the oxide surface reveals a defect area of less than 25 mm², and where the III-V wafer (W) is semiconducting.

Here, a measurement was carried out through Candela surface ellipsometry using the measurement channel QAbsPhase.

The following applies for the charge carrier concentration: At a charge carrier concentration of less than 1×10¹⁰ cm⁻³, wafers are deemed semi-insulating, at a charge carrier concentration of more than 1×10¹⁰ cm⁻³ they are deemed semiconducting. The determination of the charge carrier concentration is described in the standard “SEMI M39”.

30. III-V wafer (W) according to item 29, where the III-V wafer (W) contains silicon or sulfur as dopant.

31. III-V wafer (W) according to item 30, where the III-V wafer is a GaAs wafer and contains silicon as dopant.

32. III-V wafer (W) according to item 30, where the III-V wafer is an InP wafer and contains sulfur as dopant.

33. At least one-sided polished, dried, and semi-insulating III-V wafer (W) with an oxide layer on the entire surface, in which a surface that shows an altered surface oxide composition compared to the rest of the entire surface of the III-V wafer is less than 25 mm².

Here, a measurement was also carried out via Candela surface ellipsometry using the measurement channel QAbsPhase.

34. III-V wafer (W) according to any one of items 29 to 33, in which the charge carrier concentration lies between 1×10¹⁸ cm⁻³ and 9×10¹⁸ cm⁻³.

35. InP wafer (W) according to any one of items 29 to 34, whose oxide surface reveals a defect area of less than 20 mm², preferably of less than 15 mm², more preferably of less than 10 mm², even more preferably of less than 5 mm².

36. III-V wafer (W) according to any one of items 23 to 35, in which the diameter of the wafer is at least 150 mm.

37. III-V wafer (W) according to any one of items 23 to 36, where the diameter of the wafer is at least 200 mm.

38. GaAs wafer (W), being doped with silicon, having a charge carrier concentration of between 1×10¹⁸ cm⁻³ and 3×10¹⁸ cm⁻³, in which the surface oxide reveals a defect area of less than 25 mm².

39. InP wafer (W), doped with sulfur, having a charge carrier concentration of between 1.5×10¹⁸ cm⁻³ und 9×10¹⁸ cm⁻³, and in which the surface oxide reveals a defect area of less than 25 mm².

40. InP wafer (W), doped with sulfur, having a charge carrier concentration of between 1.5×10¹⁸ cm⁻³ und 9×10¹⁸ cm⁻³, and in which the surface oxide reveals a defect area of less than 20 mm², preferably of less than 15 mm², more preferably of less than 10 mm², and even more preferably of less than 5 mm².

41. III-V wafer (W) according to any one of items 23 to 39 or the InP wafer according to item 39 or 40, in which the defect area is a contiguous area.

42. III-V wafer (W) according to item 41, in which at least a part of the defect area is in contact with the edge of the wafer.

43. III-V wafer (W) according to item 41 or 42, in which at least a part of the defect area is at maximum 5 mm away from the edge of the wafer.

44. III-V wafer (W) according to any one of items 41 to 43, where the entire defect area is located within a circular ring between the edge of the wafer and a virtual circular line that is at maximum 10 mm away from the edge of the wafer.

45. III-V wafer (W) according to any one of items 41 to 44, in which the entire defect area is located within a circular ring between the edge of the wafer and a virtual circular line that is a maximum of 10.5 mm away from the edge of the wafer.

46. III-V wafer (W) according to any one of items 41 to 45, in which the entire defect area is located within a circular ring between the edge of the wafer and a virtual circular line that is a maximum of 10 mm away from the edge of the wafer.

47. III-V wafer (W) according to any one of items 41 to 46, in which the wafer has a straight ground section or a notch at a part of the edge, and the defect area is located opposite to the straight ground section or the notch.

The straight ground section or notch serves as a ‘recognition feature’ for transferring the azimuthal orientation of the crystal lattice, which is determined by X-ray methods at the wafer manufacturer, to the exposure systems in a lithography line when the wafer is used for the production of electronic components (growth of epitaxial layers on the wafer, lithography, etc.).

48. Device for drying of wafers, comprising:
a bath (1) with liquid;
a wedge (2),
at least one bearing device (5), that is vertically movable;
where at least one rack (3; 31, 32) can be mounted into the bearing device (5),
which comprises at least one rack (3; 31, 32):
a pair of first lateral guiding devices (3a, 3a′), a pair of second lateral guiding devices (3b, 3b′) and a pair of third lateral guiding devices (3c, 3c′),
where the pair of first lateral guiding devices (3a, 3a′) is arranged below the pair of second lateral guiding devices (3b, 3b′), and the pair of second lateral guiding devices (3b, 3b′) is arranged below the pair of third lateral guiding devices (3c, 3c′), and
where the distance between the pair of first lateral guiding devices (3a, 3a′) from each other is smaller than the distance between the pair of second lateral guiding devices (3b, 3b′) from each other, and the distance between the pair of second lateral guiding devices (3b, 3b′) from each other is smaller than the distance between the pair of third lateral guiding devices (3c, 3c′) from each other,
where the wedge (2) is arranged below the rack (3) and vertically movable separately from the bearing device (5).

Here, vertically means moving out of or into the bath, i.e., parallel to the direction of gravity.

49. Device according to item 48, in which the wedge (2) is vertically movable independent from the bearing device (5) or rack (3).

50. Device according to item 48 or 49, in which the wedge (2) comprises at least two wedge parts (2a, 2b), where both wedge parts (2a, 2b) are vertically movable independent from each other.

51. Device according to item 50, in which at least a first rack (31) may be inserted into the bearing device (5) in a way that the center of at least the first rack (31) is positioned above the tip of the first wedge section (2a), and further, a second rack (32) may be inserted in a way that the center of the second rack (32) is positioned above the tip of the second wedge section (2b).

52. Device according to item 51, in which the first rack (31) is adapted to hold a wafer (W1) with a first diameter, and the second rack (32) is adapted to hold a wafer (W2) with a second diameter, wherein the first diameter is smaller than the second diameter.

53. Device according to any one of items 50 to 52, in which the tip(s) of the first wedge section (2a) and/or the second wedge section (2b) is formed as a triangle, preferably as a right-angled triangle.

54. Device according to any one of items 50 to 53, in which the first wedge section (2a) is divided into two parts, and two sections are present, in which the first wedge section (2a) and the second wedge section (2b) are arranged next to each other.

### BRIEF DESCRIPTION OF THE DRAWINGS

The following provides a more detailed description of preferred embodiments of the present invention with reference to the accompanying figures.

FIG. 1 shows a Marangoni drying process according to the state-of-the-art.

FIG. 1a) shows an arrangement of a wafer in a bath according to the state-of-the-art.

FIG. 1b) shows the sequence of process steps, and

FIG. 1c) shows an obtained wafer with a corresponding residual droplet according to the state-of-the-art.

FIG. 2 shows an additional process for Marangoni drying according to the state-of-the-art.

FIG. 2a) shows an arrangement of a wafer in a bath according to the state-of-the-art.

FIG. 2b) shows the sequence of process steps, and

FIG. 2c) shows an obtained wafer with a corresponding residual droplet according to the state-of-the-art.

FIG. 3 shows a process for producing a cleaned and dried wafer, such as GaAs wafers, using Marangoni drying according to one embodiment of the present invention.

FIG. 3a) shows an arrangement of a wafer in a bath,

FIG. 3b) shows the sequence of process steps, and

FIG. 3c) shows a residual droplet at the contact point of an obtained wafer according to the embodiment of the invention.

FIG. 4 shows a process for producing a cleaned and dried wafer, such as a GaAs or InP wafer, according to one embodiment of the invention using a Marangoni drying according to another embodiment. FIG. 4a) shows the process steps, FIG. 4b) shows potential constructive details for the fixation of the wafers above the liquid level.

FIG. 5 shows a detail of the precise sequence of step d) from FIG. 4 according to a first variation.

FIG. 6 shows a detail of the precise sequence of step d) from FIG. 4 according to a second variation.

FIG. 7 shows a detail of the precise sequence of step d) from FIG. 4 according to a third variation.

FIG. 8 shows a concept for step d) from FIG. 4 according to a fourth variation.

FIG. 9 shows another embodiment of a device for drying wafers.

FIG. 10 shows two examples for racks in which multiple wafers can be held.

FIG. 11 shows an example for an evaluation routine of wafers or wafer groups, respectively, in which data acquired using a Candela surface ellipsometer can be processed accordingly.

FIG. 12 shows several examples of residual droplets or their residues that can be detected using a Candela surface ellipsometer and measured accordingly in terms of their area.

FIG. 13 shows another example of an evaluation routine of wafers or wafer groups, respectively, in which data acquired using a Candela surface ellipsometer can be processed accordingly.

FIG. 14 shows a comparison between semi-insulating (in this case undoped) GaAs wafers, which were dried using a process according to an embodiment of the invention according to FIG. 3, and wafers, which were dried according to a process according to FIG. 1, regarding their defect area.

FIG. 15 shows a comparison between semiconducting (in this case Si-doped) GaAs wafers, which were dried using a process according to an embodiment of the invention according to FIG. 3, and wafers, which were dried according to a process according to FIG. 1, regarding their defect area.

FIG. 16 shows a comparison between semiconducting (in this case sulfur-doped) InP wafers, which were dried using a process according to an embodiment of the invention according to FIG. 3, and wafers, which were dried according to a process according to FIG. 1, regarding their defect area.

FIG. 17 shows a view of a device for drying of wafers from above.

FIG. 18 shows views of the side of a device for drying of wafers (in different states) according to another embodiment of the present invention.

FIG. 19 shows a comparison between semi-insulating (in this case Fe-doped) InP wafers, which were dried using a process according to an embodiment of the invention according to FIG. 3, and wafers, which were dried according to a process according to FIG. 1, regarding their defect area.

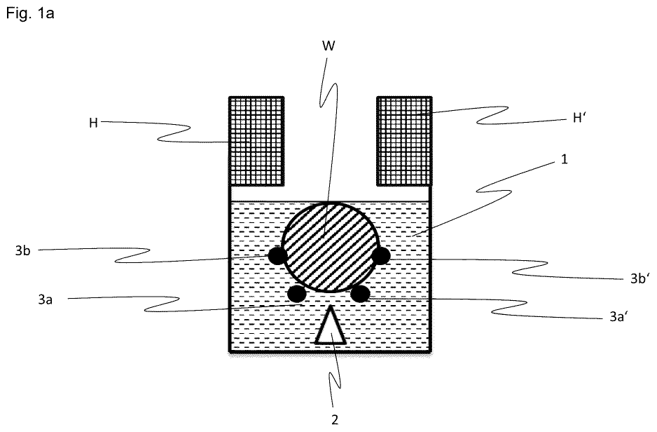

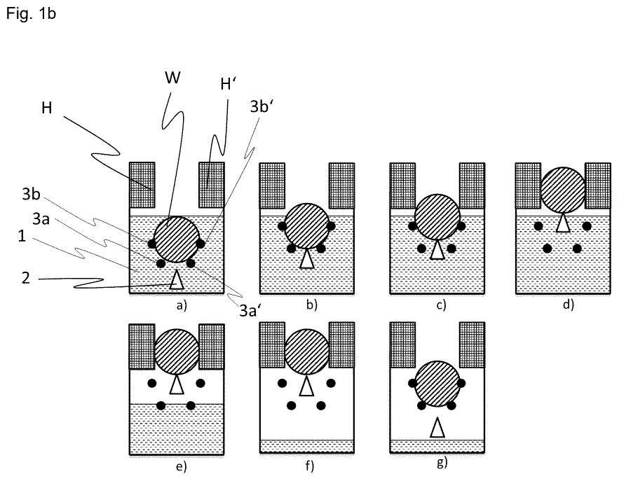

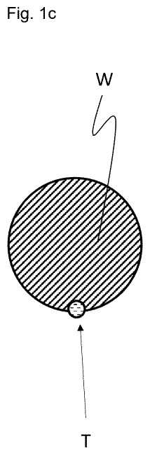

FIG. 1 shows a process for lifting one or more wafer(s) W out of a bath 1.

In FIG. 1a), a bath 1 is shown (this contains deionized rinse water, for example, to which a surface-active substance, such as isopropanol, has been added); herein a wafer W is contained. Above the water surface, holding devices H and H′ are located, and the wafer W is being held by two pairs of lateral guiding devices 3a and 3a′ as well as 3b and 3′. Below the wafer, a corresponding wedge 2 is located, which is vertically movable and used while lifting of the wafer.

In FIG. 1b), the process steps are described in more detail.

In step a) of the process according to the state-of-the-art, the wafer W is located below the liquid level of the bath 1, and the first lateral guiding devices 3a, 3a′ as well as the second lateral first guiding devices 3b, 3b′ are also located below the liquid level. The wedge 2 is located below the wafer W and does not contact it.

In step b), during the upward movement of the first and second lateral guiding devices 3a, 3a′, 3b, 3b′, the wedge 2 is moved closer toward the wafer W. Yet, the former does not necessarily need to contact the latter. A part of the wafer W is now located above the liquid level. However, the first and second lateral guiding devices 3a, 3a′, 3b, 3b′ are still located below the liquid level.

The wafer W resides in a state in which it cannot yet be held by the holding devices H and H′. It is not yet lifted out of the bath.

In step c), only the wedge 2 is vertically moved upward and pushes the wafer W partially out of the water bath; the wafer W is already contacting the holding devices H and H'. These may, for example, be provided in the lid of the dryer. Yet, the first and second lateral guiding devices 3a, 3a′, 3b, 3b′ are still located below the liquid level, and have not yet moved further relative to step b). Since the wedge 2 has pushed the wafer W further upward, the first lateral guiding devices 3a, 3a′ do no longer contact the wafer W-yet the second lateral guiding devices 3b, 3b′ do still contact the wafer W.

In step d), the wafer W is pushed even further upward by the wedge 2 now, the second lateral guiding devices 3b, 3b′ do also no longer contact the wafer W. Yet, the wafer W is still held by the holding devices H, H′.

In step e), liquid is drained from the bath 1. The liquid level is below the wafer W. Hence, the wafer W has been dried. The water level of the bath is lowered, i.e., the water is drained, in order to ensure drying of the first and second lateral guiding devices 3a, 3a′, 3b, 3b′. The wedge 2 still contacts the wafer W. The first and second lateral guiding devices 3a, 3a′, 3b, 3b′ have not been moving further relative to step c).

In step f), the surface of the water bath 1 is lowered thus far to place the first and second lateral guiding devices 3a, 3a′, 3b, 3b′ and the wedge 2 above the water level and hence have dried as well. The wedge 2 still contacts the wafer W.

In step g), the wedge 2 is being lowered. Through the downward movement of the wedge 2, the wafer W is again being held by the first and second lateral guiding devices 3a, 3a′, 3b, 3b′, that have already been dried, and thus contacts them.

To prevent a contact between the wafer W with the first and second lateral guiding devices 3a, 3a′, 3b, 3b′ while passing through the liquid surface of the bath 1, the wafer W is pushed by the vertically upward moving wedge 2 out of the first and second lateral guiding devices 3a, 3a′, 3b, 3b′ and is subsequently only being held by the holding devices H. Residual droplets between wafer W and the first and second lateral guiding devices 3a, 3a′, 3b, 3b′ are being prevented. The holding devices H, H′ are now above the water level, and are thus still dry and cannot cause any residual droplets. While passing through the water surface, a residual droplet can only be present between the wafer W and the wedge 2. However, the disadvantage of this method is that a challenging process management is being present with very high requirements for the spatial adjustment of the moving parts relative to each other, particularly for the wedge 2 and the first and second lateral guiding devices 3a, 3a′, 3b, 3b′. As the holding devices H, H′ are continuously adjusted to one size of a wafer, wafers with different sizes cannot be dried according to such method-a separate drying apparatus would be required for each size.

FIG. 1c) clearly shows that a residual droplet T is present here at the lower edge of the wafer W, which evolves between the contact of the wafer W and the wedge 2.

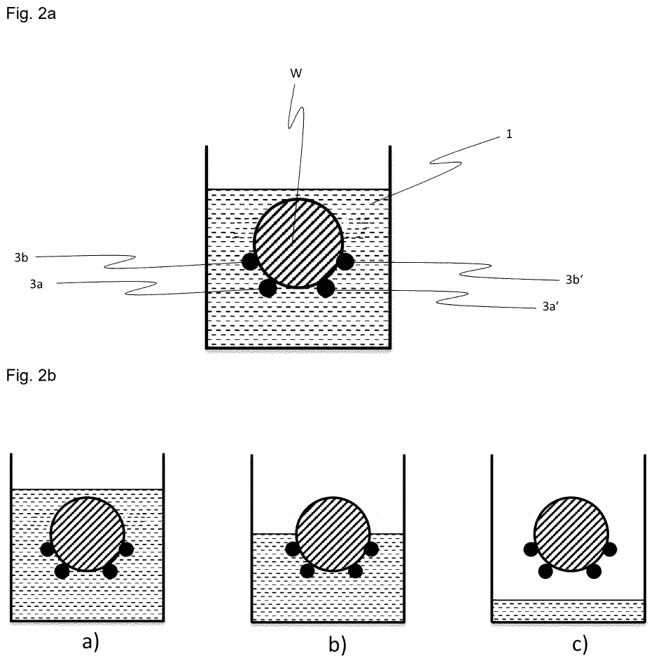

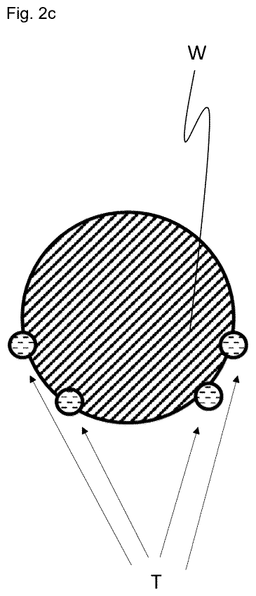

FIG. 2 shows an alternative process for drying of a single or multiple wafer(s) from a bath 1, which is also known from the prior art.

FIG. 2 a) clearly shows that, in turn, the wafer W is being held by two pairs of first and second lateral guiding devices 3a, 3a′, 3b, 3b′. These, in turn, are located in a bath 1.

From FIG. 2b), the individual steps of the process emerge:

In step a), the wafer is below the water surface and being held by the first and second lateral guiding devices 3a, 3a′, 3b, 3b′. Here, the first and second lateral guiding devices 3a, 3a′, 3b, 3b′ are not yet being moved. The water bath 1, which contains water that is enriched with isopropanol close to its surface layer, is drained at a predetermined speed.

In step b), the liquid surface is above the pair of second lateral guiding devices 3b, 3b′.

In step c), the water is below the wafer W, the first and second lateral guiding devices 3a, 3a′ as well as 3b, 3b′ are above the liquid surface.

Due to the contact between the first and second lateral guiding devices 3a, 3a′, 3b, 3b′ when lowering the liquid level, the contact points of the wafer with the first and second lateral guiding devices 3a, 3a′, 3b, 3b′ often have residual droplets, which adversely affect the quality of the wafers accordingly. Also, the quality of later grown epitaxial layers is negatively affected, this may lead to a lower yield of component parts. However, an advantage of said method is that it is technically less challenging, and it has the potential to dry wafers of different sizes.

FIG. 2c) shows a wafer W with residual droplets T at all four contact points.

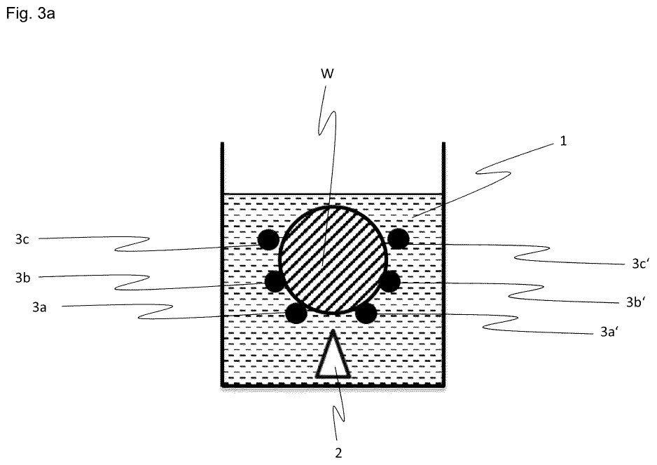

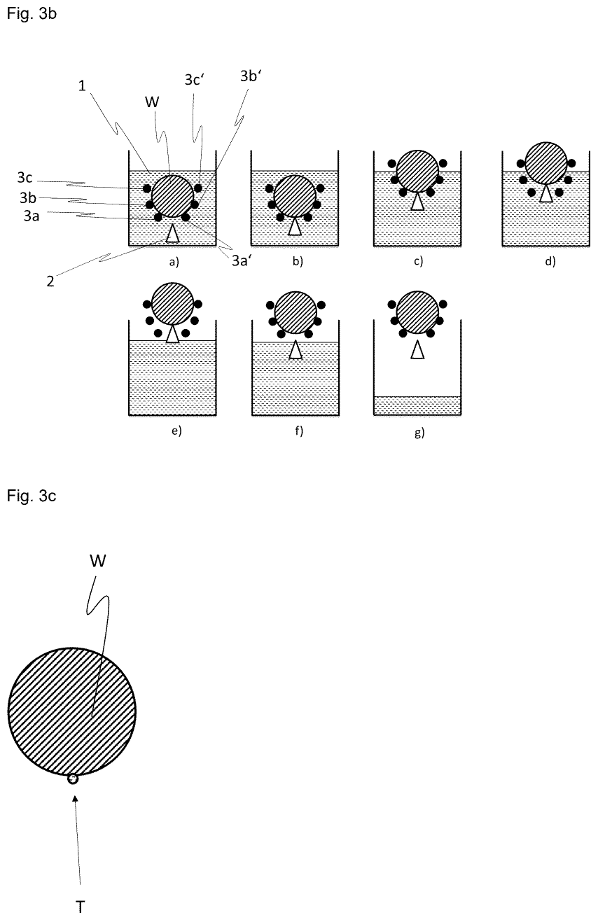

FIG. 3 shows a method for wafer drying according to the present invention.

In FIG. 3a), a state is shown in which the wafer W is fully submerged in the bath 1. Here, however, three pairs of lateral guiding devices 3a, 3a′, 3b, 3b′, as well as 3c, 3c′ are present holding the wafer, wherein the pair of first lateral guiding devices 3a, 3a′ is arranged below the pair of second lateral guiding devices 3b, 3b′, and the pair of second lateral guiding devices 3b, 3b′ is arranged below the pair of third lateral guiding devices 3c, 3c′. The distance between the pair of first lateral guiding devices 3a, 3a′ from each other is smaller than the distance between the pair of second lateral guiding devices 3b, 3b′ from each other, and the distance between the pair of second lateral guiding devices 3b, 3b′ from each other is smaller than the distance between the pair of third lateral guiding devices 3c, 3c′ from each other.

In FIG. 3a), the third lateral guiding devices 3c, 3c′ do not contact the wafer W. A wedge 2 is provided below the wafer.

In FIG. 3b), the individual steps are described in more detail.

In step a), the wafer W is located below the liquid surface of the bath 1 and being held by the pair of first lateral guiding devices 3a, 3a′ as well as the pair of second lateral guiding devices 3b, 3b′. The wedge does not contact the wafer. The pair of third lateral guiding devices 3c, 3c′ does not contact the wafer.

In step b), the wedge is moved towards the wafer in a way that the tip of the wedge contacts the wafer.

In step c), the lateral guiding devices 3a, 3a′, 3b, 3b′ and 3c, 3c′ as well as the wedge 2 are moved upwards. Here, the third lateral guiding devices 3c, 3c′ that have already passed the water surface are, however, not in contact with the wafer, i.e., they do not contact it. The wedge 2 remains being moved towards the wafer W and contacting it, however, still below the water surface.

In step d), the water level is still located between the pair of second lateral guiding devices 3b, 3b′ and the third lateral guiding devices 3c, 3c′. Yet, the wafer W is only being slightly lifted by the wedge 2, so that the wafer no longer contacts the first pair of lateral guiding devices 3a, 3a′ as well as the second pair of lateral guiding devices 3b, 3b′. Rather, the wafer W is in contact with the third pair of lateral guiding devices 3c, 3c′ above the liquid surface.

Hence, the wafer is now being held by the wedge 2 as well as by the third pair of lateral guiding devices 3c, 3c′.

In step e), the wafer W as well as the tip of the wedge 2 as well as the first pair of lateral guiding devices 3a, 3a′, the second pair of lateral guiding devices 3b, 3b′ as well as the third pair of lateral guiding devices 3c, 3c′ are above the water surface.

In step f), the wedge 2 is being lowered, the wafer is being held by the wedge 2 as well as the first pair of lateral guiding devices 3a, 3a′ as well as the second pair of lateral guiding devices 3b, 3b′ which are now already dried. The third lateral guiding devices 3c, 3c′ are no longer contacting the wafer W.

In step g), the water level has been lowered, the position of the wafer W relative to the three lateral guiding devices 3a, 3a′, 3b, 3b′ as well as 3c, 3c′ as well as of the wedge 2 has not changed compared to step f).

While passing through the water surface, there is only one contact point between the wafer W and the wedge 2 at which a residual droplet may evolve.

In FIG. 3c), a residual droplet is shown below at the contact point of the wedge 2 which, however, does not necessarily need to occur, and if it occurs, is smaller compared to the method according to FIG. 1 and FIG. 2.

The speed of movement of the lateral guiding devices 3a, 3a′, 3b, 3b′ and 3c, 3c′ as well as the wedge 2 are always coordinated in such a way that the resulting movement speed for the wafers is always constant und thus may be controlled. The travel path of the wafers during lifting is smaller compared to FIG. 1, leading to a shorter process time. Consequently, the contact time between the lower edge of the wafers W and the movable wedge 2 containing residual moisture is shortened by several minutes. As a result, the risk of residual droplet formation at the contact points fundamentally decreases. Due to the shorter vertical distance between wafers and lateral guiding devices 3a, 3a′, 3b, 3b′ as well as 3c, 3c′, both wafers and lateral guiding devices can be dried almost simultaneously, which shortens process time even further. This leads to a significantly increased productivity of the overall cleaning process, as the drying usually represents the slowest process step and, hence, is the limiting step for the speed of the entire process.

The adjustment effort for the setup and correction of the positions of all components (wedge as well as lateral guiding devices) is significantly reduced, a complicated alignment between the lateral guiding devices is omitted, and no inclined travel path is necessary. Further, the risk decreases that the wafer is subjected to mechanical stress, which may lead to scratches on the wafers, damaging of the wafer edge as well as wafer breakage, in case of inaccurate adjustment.

The reduced risk of residual droplets and mechanical stress for the wafers due to an inaccurate adjustment is particularly relevant for the drying of larger wafers (e.g., more than 150 mm), as the unfavorable leverage ratios compared to smaller wafer diameters would require a significantly increased adjustment effort and smaller tolerances to ensure a consistent wafer quality.

The contact time between the wedge 2 and the wafer W may be shortened from several minutes to a few seconds compared to the method in FIG. 1, which leads to a drastically reduced probability of residual droplets occurring at the only remaining first contact point (between wedge 2 and wafer W). If these residual droplets should still occur, they would be significantly smaller.

Preferably, the lifting of the wafers happens with a speed of about 1 mm/s. For the drying of the lower part of the wafers (about 1 cm), the lifting speed is significantly reduced to below 0.5 mm/s for a reduction of the contact droplets. The lifting speed is the speed at which the wafer is moving relative to the liquid level. As too strong fluctuations of the water level may be depicted in the chemical composition of the oxide layer, this speed reduction must occur step by step. Exactly when the lower edge of the wafer W has reached the water level, the wafers W must be separated from the water level at high speed (>30 mm/s, preferably >40 mm/s, more preferably >50 mm/s) and, simultaneously, the wedge 2 must be separated from the lower edge of the wafer W in the opposite direction. A precise adherence to this boundary condition is particularly required for n-doped GaAs due to its high surface tension. Only in this way can it be prevented that, on the one hand, water from the water level and, on the other hand, residual moisture from the wedge 2 will be drawn again onto the surface of the wafer.

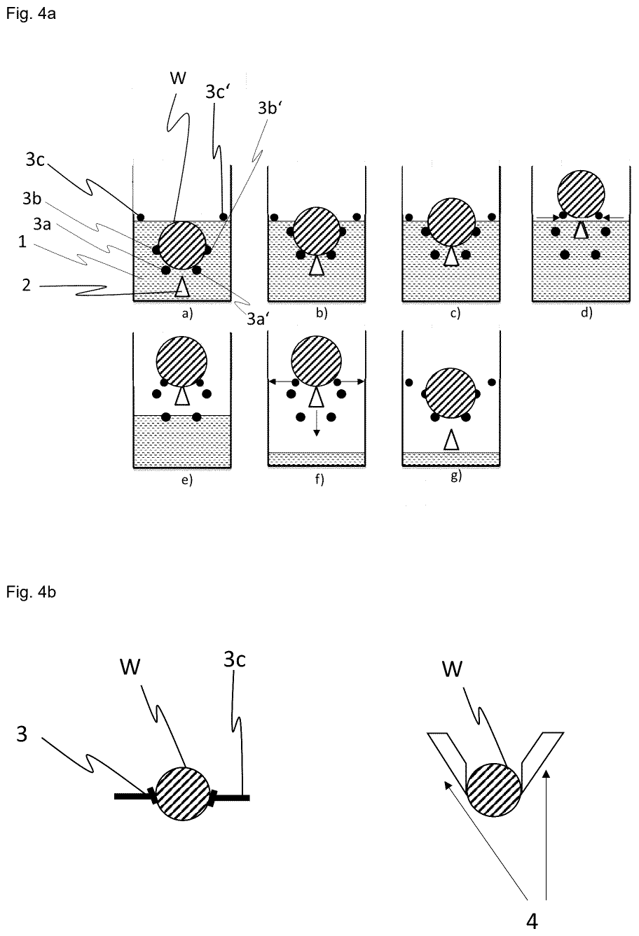

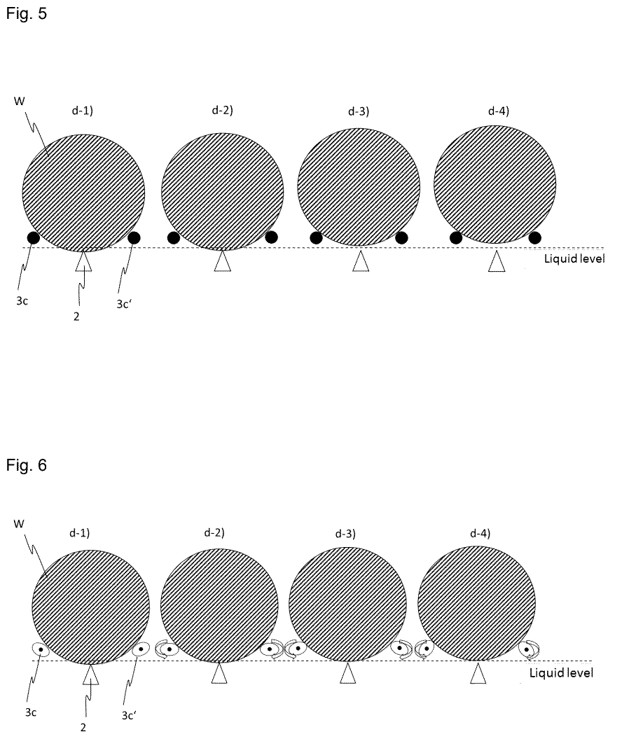

FIG. 4 shows another embodiment of the method of Marangoni drying. Particularly, the sequence of the process steps is shown in FIG. 4a).

In step a), the wafer W is below the liquid surface and being held by the first and second lateral guiding devices 3a, 3a′ as well as 3b, 3b′. The water bath 1 contains water that is enriched with isopropanol at its surface. A pair of third lateral guiding devices 3c, 3c′ is above the liquid surface, serving-so to speak-as dry transfer unit.

In step b), the wafer W is being slightly lifted by a wedge 2, a part of the wafer is above the water surface, the wedge 2 is in contact with the lower edge of the wafer W. Below the water surface, the wafer is still being held by the lateral guiding devices 3a, 3a′ and 3b, 3b′ which yet have moved slightly upward. The pair of third lateral guiding devices 3c, 3c′ is still above the water surface and not in contact with the wafer.

In step c), the position of the pair of first lateral guiding devices 3a, 3a′ as well as the pair of second lateral guiding devices 3b, 3b′ stays constant.

However, the wedge 2 has lifted the wafer further, so that the latter is only being in contact with the pair of second lateral guiding devices 3b, 3b′, and not with the pair of first lateral guiding devices 3a, 3a′. The position of the pair of third lateral guiding devices 3c, 3c′ has not changed compared to step b).

In step d), the wafer W has been lifted entirely out of the liquid bath.

The wedge 2 indeed remains below the liquid surface. Here, the pair of third lateral guiding devices 3c, 3c′ has moved horizontally, the distance between the third lateral guiding devices 3c, 3c′ has become smaller. Either the third lateral guiding devices 3c, 3c′ may have a holding function or an additional gripping device 4, as illustrated in FIG. 9 (not, however, shown in the present figure) may be used to keep the wafer W above the liquid surface. These hold the wafer W above the water surface.

In step e), the liquid level is lowered by the release of water.

In step f), the position of the first and second lateral guiding devices 3a, 3a′, 3b, 3b′ remains unchanged, yet the pair of third lateral guiding devices 3c, 3c′ is being moved horizontally, the distance between the third lateral guiding devices 3c, 3c′ is increasing again, and the wafer W now rests, among others, on the wedge 2. From the moment when the third lateral guiding devices 3c, 3c′ are no longer contacting the wafer, the wafer W is being held by the wedge 2 and the second lateral guiding devices 3b, 3b'. Hence, the wedge 2 as well as all lateral guiding devices 3a, 3a′, 3b, 3b′ as well as 3c, 3c′ are dried.

In step g), the wedge 2 is lowered so that the wafer W is again being held by the pair of first lateral guiding devices 3a, 3a′ as well as by the pair of second lateral guiding devices 3c, 3b′.

In this method, there is the peculiarity that a passing of a wafer through the water level is possible without a single contact to any tool, i.e., neither to any of the guiding devices 3a, 3a′, 3b, 3b′ as well as 3c, 3c′ nor to the wedge 2. The wedge 2 remains below the liquid surface in all process steps of the wafer lifting, the pair of third lateral guiding devices 3c, 3c′ always remains above the liquid surface and thus never gets wet.

FIG. 4b) exemplarily shows how the wafer may be additionally held from step d) on. On the left, the third lateral guiding devices 3c, 3c′ are illustrated in a T shape, that leads to the wafer W being held better. On the right, gripping devices 4 can be recognized, which may additionally hold the wafer W above the liquid surface, and which may be adjustable to the wafer diameter. In general, the embodiments of the present method with a draining of water in the process bath (FIG. 3 and FIG. 4) only then work when the wafer is completely above the liquid surface. This allows for a continuous flow with ultrapure water (so-called overflow). The surface of the liquid level, on which particles may float, is thus always well-circulated, and exchange of liquids takes place. In a method according to FIG. 2, the liquid level is lowered while the wafer W is at least still partially in the bath. An overflow at the liquid surface is then no longer possible, particles may then easily accumulate there, and adhere to the drying wafers W-which then deteriorates the quality of the epitaxial layer.

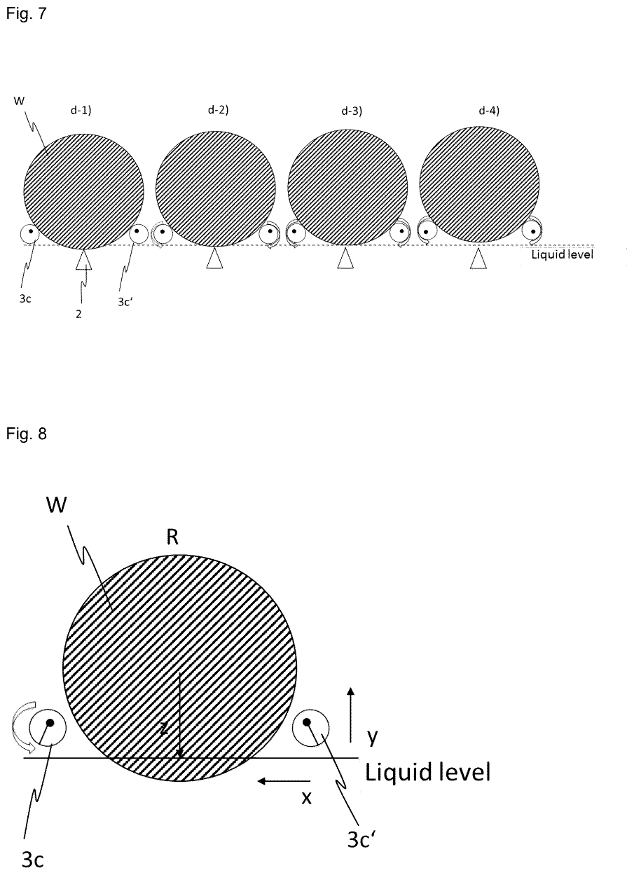

FIG. 5 provides a more detailed representation of the sequence of step d) from FIG. 4 according to a first variation-sub-steps are, so to speak, being illustrated. Here, it is illustrated that the wafer W is located almost completely above the liquid level in step d-1). The wedge 2 is located below the liquid level, and the pair of third lateral guiding devices 3c, 3c′ is located above the liquid level and adjacent to the wafer W. In steps d-2), d-3) and d-4), the distance of the pair of third lateral guiding devices 3c, 3c′ is continuously reduced, yet the wedge 2 remains below the liquid surface. In step d-3), the entire wafer is already above the water surface. In step d-4), the wafer has moved slightly further up. The third lateral guiding devices 3c, 3c′ are hence drying transfer units, which are always above the liquid surface and thus never get wet. A horizontal movement of the third lateral guiding devices 3c, 3c′ is all that is necessary. The wafer slides on the third lateral guiding devices 3c, 3c′.

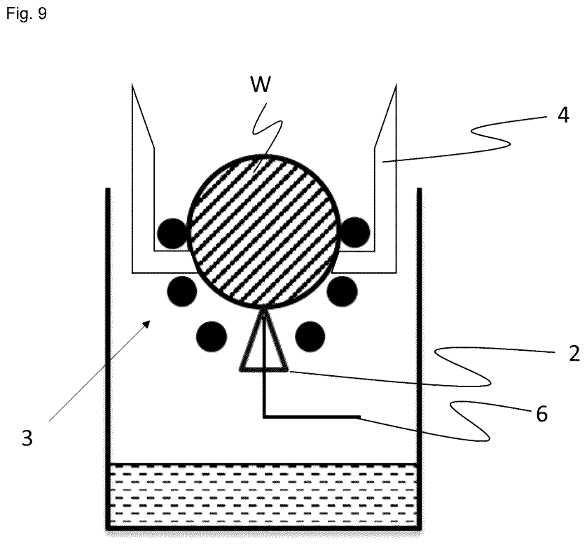

FIG. 6 provides a more detailed representation of the sequence of step d) from FIG. 4 according to a second variation-sub-steps are, so to speak, being illustrated. Here, only the structure of the third lateral guiding devices 3c, 3c′ is different. These are oval-shaped, a horizontal movement and a rotational motion are necessary to move the wafer W. Also, here, only the lifting of the last millimeters of the entire wafer W out of the liquid bath, as illustrated in step d) in FIG. 4, is described accordingly in greater detail. In step d-1), the wafer rests against two obliquely positioned oval third lateral guiding devices 3c, 3c′, where the large side of the oval shape rests against the wafer. The wafer is almost completely lifted out of the water bath, it is only one millimeter that it still dips into the water. The wedge 2 always remains under water. Now, in step d-2), the oval third lateral guiding devices 3c, 3c′ rotate so that the wafer is rotated a bit further upward. In steps d-3) and d-4), the third lateral guiding devices 3c, 3c′ rotate further until the wafer is located completely above the liquid level.

FIG. 7 provides a more detailed representation of the sequence of step d) from FIG. 4 according to a third variation-sub-steps are, so to speak, being illustrated. Here, the drying transfer units, i.e., the third lateral guiding devices 3c, 3c′, show an eccentric axis. A horizontal movement and a rotational motion are necessary to move the wafers W. In step d-1), a small portion of the wafer is still below the liquid level; in step d-2), the third lateral guiding devices 3c, 3c′ rotate, which is why the wafer is slightly moved upward; in step d-3), the third lateral guiding devices 3c, 3c′ have turned further so that the wafer is already above the liquid level; in step d-4), the wafer is lifted a little way above the liquid surface. The wedge 2 always remains under water.

FIG. 8 shows a representation of Al-supported adaptive control for the wafer lifting. Here, the wafer W having a radius R is shown and, further, the pair of third lateral guiding devices 3c, 3c′ is asymmetrically shown. The interplay between the movements of the wedge 2 (not shown here), the third lateral guiding devices 3c, 3c′ and the wafer relative to the position of the water level is complex, particularly for the drying of wafers of different diameters. According to conventional methods, complex movement patterns would have to be developed, and the mechanics would need to be extensively calibrated for each diameter. Here, an AI-supported adaptive control may be utilized. Wafers, that are arranged in a rack, are recorded using cameras (not shown here), namely, at least the first and the last wafer of a rack. The cameras are fixed and installed above the water surface, and the third lateral guiding devices 3c, 3c′ are highlighted with colors in order to facilitate image recognition. A trained neural network with Al-based image recognition may then determine the distance between the wafer center and the water level (parameter z in FIG. 8), the position (parameters x, y in FIG. 8), as well as possibly the rotation position of the third lateral guiding devices 3c, 3c′. These data may then control the program flow, particularly the movement of the wedge 2 in vertical direction, the movement of the third lateral guiding devices 3c, 3c′ (horizontal movement and possibly rotation), and further additional important process parameters (such as the draining or the DI water supply) may be controlled accordingly. The monitoring of the first and last wafer in a rack enable detecting a tilt of the rack axis relative to the plane of the water surface, and, if necessary, to take appropriate countermeasures.

FIG. 9 shows another embodiment of a corresponding device for drying of wafers. Except for the rack 3 and the wedge 2, gripping devices 4 are provided, which are designed to grip the wafer as far as the wafer rises above the water surface. As soon as the gripping devices 4 have gripped the wafer, the wedge 2, which is still under water, may be lowered (not shown in the figure). The rack and the gripper move with the same speed upward and the wafer passes through the water surface, without being held by the wedge 2 at the point of passage. Hence, a residual droplet is prevented from forming. Here, a suction device 6 is provided within the wedge 2.

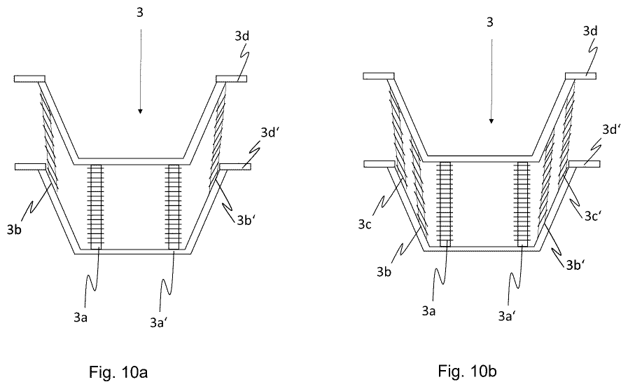

FIG. 10 shows two racks. FIG. 10 a) shows a rack 3 according to the state-of-the-art, which may be used in a method according to FIG. 1, for instance. Here, two head parts 3d, 3d′ are present, between which two pairs of lateral guiding devices 3a, 3a′ as well as 3b, 3b′ are arranged. Through these, the wafers W (not shown here) may be held. The first lateral guiding devices 3a, 3a′ as well as the second lateral guiding devices 3b, 3b′ each show elevations (not shown here in detail)-these form a comb-like structure that cannot hold individual wafers W (not shown here)-so that the wafers cannot contact each other or be tilted. The pair of first lateral guiding devices 3a, 3a′ is arranged below the second lateral guiding devices 3b, 3b′. The distance between the pair of first lateral guiding devices 3a, 3a′ from each other is smaller than the distance between the second lateral guiding devices 3b, 3b′ from each other.

FIG. 10 b) shows a rack 3 that may be used in a method according to the present invention according to FIG. 3. In contrast to FIG. 4a), here, a pair of third lateral guiding devices 3c, 3c′ is arranged above the pair of second lateral guiding devices 3b, 3b′. The distance between the pair of first lateral guiding devices 3a, 3a′ from each other is smaller than the distance between the second lateral guiding devices 3b, 3b′ from each other, and the distance between the pair of second lateral guiding devices 3b, 3b′ from each other is smaller than the distance between the third lateral guiding devices 3c, 3c′ from each other. Hence, the possibility exists to hold a wafer W (not shown here) at multiple points, unlike in FIG. 4a. The first lateral guiding devices 3a, 3a′, the second lateral guiding devices 3b, 3b′ and the third lateral guiding devices 3c, 3c′ each show elevations (not shown here in detail)—which form a comb-like structure that may hold individual wafers W (not shown here)—so that wafers cannot contact each other or be tilted.

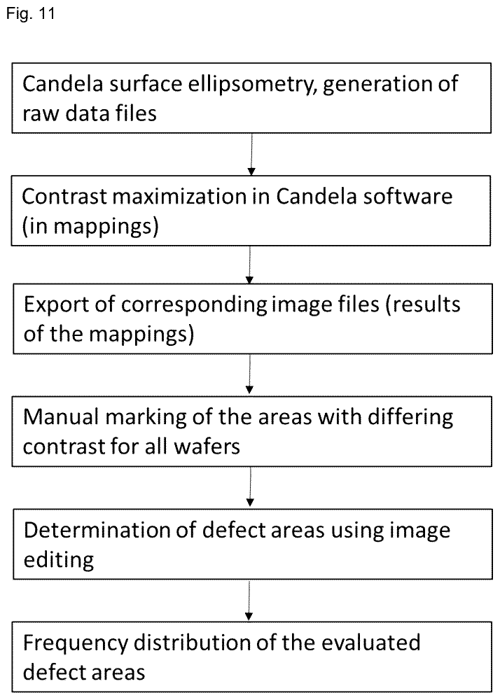

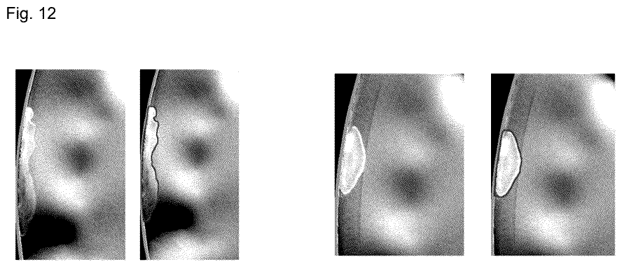

FIG. 11 shows a corresponding evaluation routine for measurements, in which the homogeneity of the oxide surface layer of wafers according to the present invention may be evaluated: Using the Candela surface ellipsometer, raw data files are being generated. Within the software of the Candela ellipsometer, a corresponding contrast maximization is performed, which is applied for the entire mapping (the contrast is varied, for example in an image processing software for pixel graphics, until droplet residues are clearly visible on the pictures shown; here, it must be ensured that an area with droplet specific shape stands out from its surroundings). Subsequently, corresponding image files are being exported. Then, a manual marking of areas of differing contrast is carried out for all wafers, wherein marginal areas are addressed, in particular.

At the place, where the residual droplet may be formed during the drying process due to the orientation of the wafer, a 9 cm wide and 1.9 cm high square has been laid onto the wafer for the evaluation. The droplet is being identified and evaluated within this square. Thereby, it can be ensured that all possible residual droplets within a 1 cm wide ring at the outer edge of the wafer are being recorded. The use of a fictitious square is more useful and precise compared to a ring (all-round stripe) that may not easily distinguish the residual droplet from a possible laser marking at the front of the wafer during the image processing.

Afterwards, a determination of the area of the defect areas is carried out using an image processing, in which the areas may be measured accordingly. This measures the area of a delimited area.

Here, typically, there is no exclusion of margins for specific areas of the wafer—rather the entire wafer can be used further-as corresponding defects can be essentially avoided by the improved Marangoni drying method.

Here, the defect areas, that show residual droplets or effects thereof with respect to a change in oxide layer composition, are marked and measured based on the following criteria:
The area has to be on an edge of the wafer
An irregular shape is present
The area shows a differing brightness from surrounding areas (usually brighter than surrounding areas; smaller darker areas are also possible)
The shape of the area is typical of a water residue (such as a droplet shape, a shape with spherical/ellipsoidal/oval elements, elongated and branched shape).

This results in a frequency distribution of the determined defect areas.

FIG. 12 shows two examples of droplets at the edge of the wafers that are each being marked and whose area is being measured. Here, it is difficult to perform an automated evaluation, as contrast variations in the wafers may, for example, occur through other effects (shown in black in FIG. 12), which however must not be confused with the droplet at the edge of the wafer.

Accordingly, a manual evaluation has to be performed here, in which care is always taken that the droplets originate from the edge of the wafer and a corresponding shape may also be logically assigned to the shape of a droplet. An entirely angular shape may accordingly not be assigned to a droplet.

Edges with finely serrated notches, for example, cannot be assigned to a droplet either, as the surface tension of water would not permit the evolution of such shape. However, a shape with irregular edge sections is possible, as can be seen in the left illustration in FIG. 12.

Defects develop due to the adhering droplets through contact of the wafer with rack or wedge when passing through the liquid surface during drying, which may cause spots and hence “defects”. According to the invention, however, less spots, preferably only one single spot, and/or an overall minimized spot areas remain, whereas multiple and overall larger spot areas usually remain for drying methods according to the state-of-the-art.

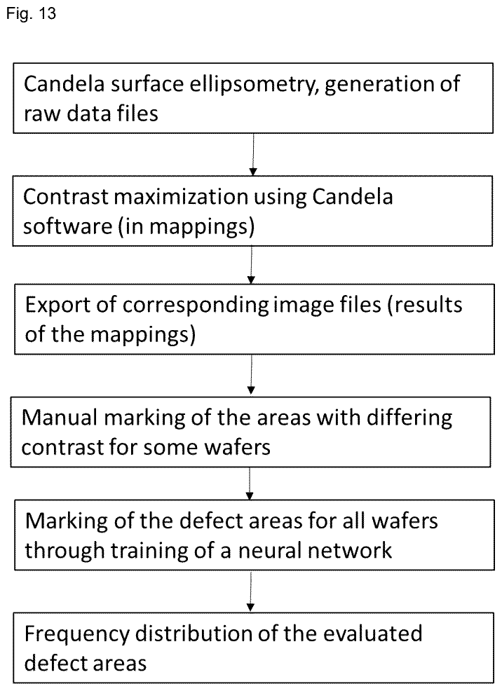

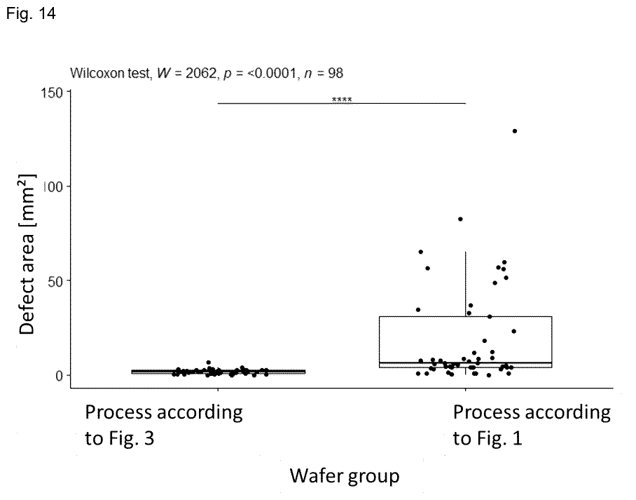

In FIG. 13 an alternative for the evaluation routine is presented. Here, a manual marking of areas of differing contrast is only performed for several wafers, and then, with the help of a training of a neural network, all remaining wafers are evaluated, and the defect areas are here evaluated accordingly. As the appearance of the droplet residues may reveal very different contrasts, a fragmentation of the droplet areas with the help of a neural network was conducted. The neural network was trained using a TensorFlow-Keras platform. A UNet structure with a resnet 34 backbone was used as model (U-Net: Convolutional Networks for Biomedical Image Segmentation“, Olaf Ronneberger, Philipp Fischer, Thomas Brox, arXiv 2015, https://doi.org/10.48550/arxiv.1505.04597; http://lmb.informatik.uni-freiburg.de/people/ronneber/u-net).

The segmented areas were visually checked for plausibility for all images and, if necessary, added to the training dataset for retraining the network. This process was iteratively carried out until the automatic segmentation matched with the visual assessment in more than 98% of all images. The areas segmented in this way are then automatically selected by conventional image processing (e.g., OpenCV: https://opencv.org/) in a second step and measured in their areal extent.

Hence, the contrasts are not evaluated based on threshold values but rather visually or by a trained algorithm or a neural network based on their extent; here, the absolute value of the measurement signal is not being considered and only the recognizability of droplet areas is considered. The evaluation proceeds outside the Candela ellipsometer.

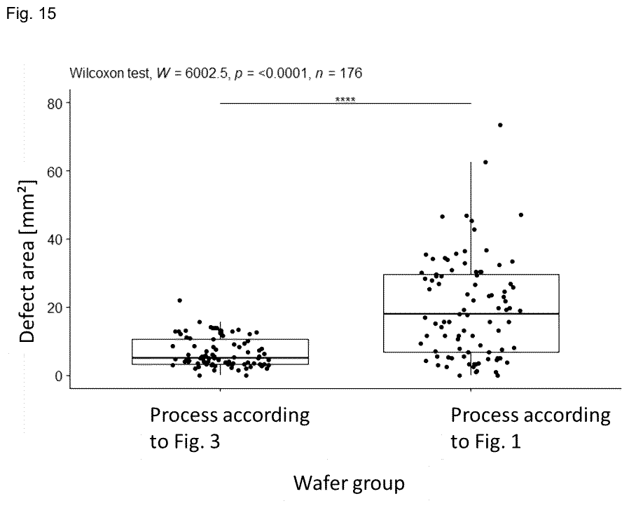

FIG. 14 shows a result of the measurement of defect areas of two corresponding wafer groups of semi-insulating, undoped GaAs wafers with a diameter of 150 mm; on the right, of wafers that were dried using a conventional Marangoni drying (according to FIG. 1) and, on the left, of wafers that were dried using an improved Marangoni drying according to the present invention (FIG. 3).

For undoped wafers, it could be shown that the spread of different defect areas is smaller for wafers produced according to the new method, and that the absolute defect area is smaller (lower than 5 mm²).

The defect area corresponds to the area that has been measured by the surface measurement using the Candela ellipsometry. From a chemical standpoint, there is an inhomogeneous composition of the surface oxide present-accordingly, defect areas are areas of the surface oxide, in which the oxide composition is inhomogeneous.

As the droplet size in the data is not normally distributed, a normal t-test cannot be performed. In these cases, the Wilcoxon test, that does not make any assumptions about the underlying distributions, is suitable. In this test, rank sums of the observed values are calculated, which are approximately normally distributed and allow for a statistical statement. As the droplet sizes of both methods are significantly different, a one-tailed test with a confidence interval of 0.95 was performed. The parameter n indicates the total number of values; if the p-value is below a typical value of 0.05, the null hypothesis can be rejected (in this case: the droplet sizes obtained by the method according to FIG. 3 are larger than the droplet sizes obtained by the method according to FIG. 1). The very small p-values (<0.0001) of the data thus show very significantly that the droplet sizes obtained by the method according to FIG. 3 are smaller. The parameter W refers to the rank sum of one of the two groups.

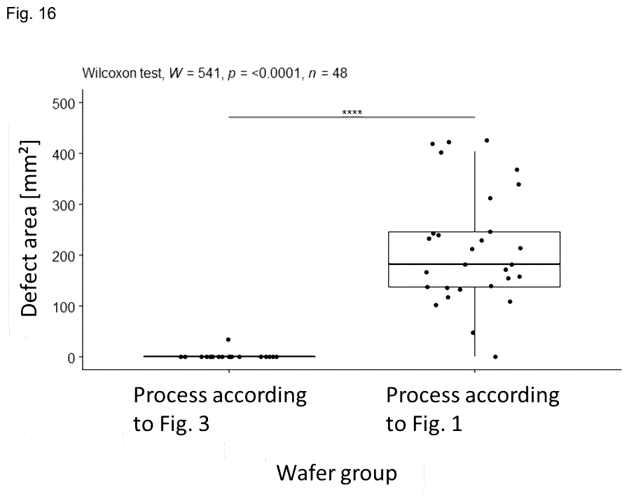

FIG. 15 shows a result of a measurement of the defect areas of two corresponding wafer groups of semi-insulating, silicon-doped GaAs wafers with a diameter of 150 mm; on the right, of wafers that were dried using a conventional Marangoni drying (according to FIG. 1) and, on the left, of wafers that were dried using an improved Marangoni drying according to the present invention (FIG. 3). Using the method according to the present invention, it could also be shown that the spread is significantly smaller for Si-doped wafers and the defect area (below 25 mm²) is significantly smaller.

As the droplet size in the data is not normally distributed, a normal t-test cannot be performed. In these cases, the Wilcoxon test, that does not make any assumptions about the underlying distributions, is suitable. In this test, rank sums of the observed values are calculated, which are approximately normally distributed and allow for a statistical statement. As the droplet sizes of both methods are significantly different, a one-tailed test with a confidence interval of 0.95 was performed. The parameter n indicates the total number of values; if the p-value is below a typical value of 0.05, the null hypothesis can be rejected (in this case: the droplet sizes obtained by the method according to FIG. 3 are larger than the droplet sizes obtained by the method according to FIG. 1). The very small p-values (<0.0001) of the data thus show very significantly that the droplet sizes obtained by the method according to FIG. 3 are smaller. The parameter W refers to the rank sum of one of the two groups.

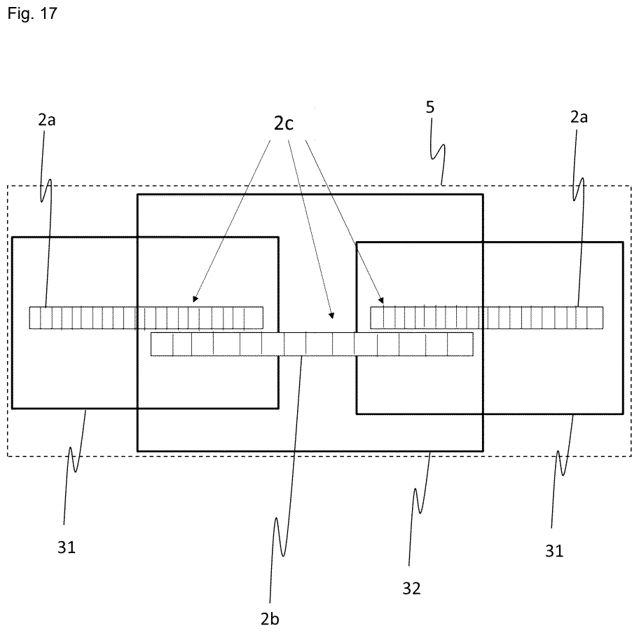

FIG. 16 shows a result of a measurement of the defect areas of two corresponding wafer groups of semiconducting, sulfur-doped InP wafers with a diameter of 100 mm; on the right, of wafers that were dried using a conventional Marangoni drying (according to FIG. 1) and, on the left, of wafers that were dried using an improved Marangoni drying according to the present invention (FIG. 3). Using the method according to the present invention, it could also be shown that the spread is significantly smaller for sulfur-doped wafers and the defect area (below 5 mm²) is significantly smaller.

The defect area corresponds to the area that has been measured by the surface measurement using the Candela ellipsometry. From a chemical standpoint, there is an inhomogeneous composition of the surface oxide present-accordingly, defect areas are areas of the surface oxide, in which the oxide composition is inhomogeneous.

As the droplet size in the data is not normally distributed, a normal t-test cannot be performed. In these cases, the Wilcoxon test, that does not make any assumptions about the underlying distributions, is suitable. In this test, rank sums of the observed values are calculated, which are approximately normally distributed and allow for a statistical statement. As the droplet sizes of both methods are significantly different, a one-tailed test with a confidence interval of 0.95 was performed. The parameter n indicates the total number of values; if the p-value is below a typical value of 0.05, the null hypothesis can be rejected (in this case: the droplet sizes obtained by the method according to FIG. 3 are larger than the droplet sizes obtained by the method according to FIG. 1). The very small p-values (<0.0001) of the data thus show very significantly that the droplet sizes obtained by the method according to FIG. 3 are smaller. The parameter W refers to the rank sum of one of the two groups.

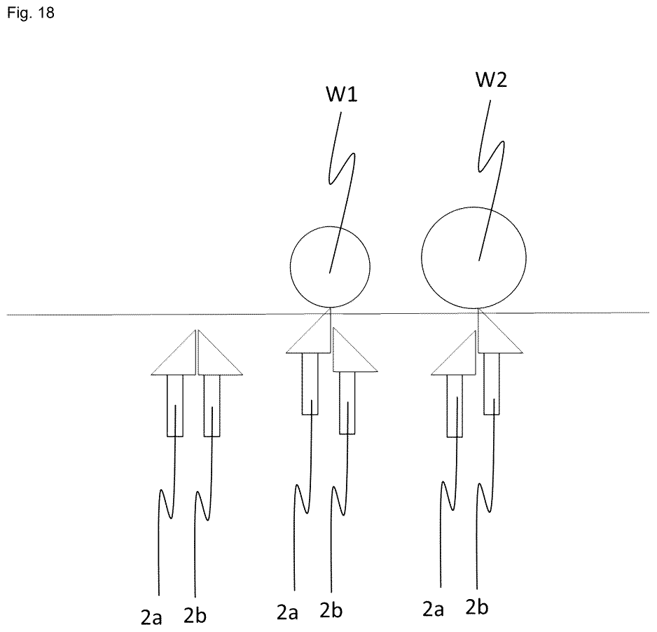

In FIG. 17, an embodiment of a device for drying of wafers according to the present invention is shown. Here, a bearing unit 5 is provided, in which several different racks 3, 31, 32 may be suspended. The racks themselves hold the wafers using guiding devices (comb rods). In the present view, either two first racks 31 or a second rack 32 are suspendable. A first rack 31 serves for drying of wafers with small diameters compared to the rack 32. Here, the wedge is constituted by two first wedge sections 2a and a second wedge section 2b, which are vertically movable separately from each other. The centers of the first racks 31 are positioned directly above the tip of the first wedge sections 2a, and the center of the second rack 32 is positioned above the tip of the second wedge section 2b. The first wedge section 2a and the second wedge section 2b also show corresponding elevations 2c that form a comb-like structure. The second rack 32 is provided for larger wafers, with diameters of more than or equal to 200 mm, for example, and the elevations 2c have a larger distance compared with the first racks 31; the racks 32 are thus longer than the first racks 31 and the wafers can no longer be lifted using identical wedges-unlike wafers with smaller diameters. The wedge sections 2a, 2b must be arranged centrally to the racks, as they must capture the wafers at a lower point. Hence, for example, the lifting of wafers with a diameter of up to 150 mm, on the one hand, and wafers larger than or equal to 200 mm, on the other hand, in a dryer is not possible according to the state-of-the-art. In the device according to the present invention, an individual wedge section (2a for smaller wafers W1, 2b for larger wafers W2) with an appropriately suitable length and an appropriately adjusted distance of the elevations 2 c is used for smaller wafers (e.g., diameter of 150 mm or less) and for larger wafers (e.g. diameter of 200 mm or more) each. As the 200 mm-wafers have a larger diameter, the distance of the elevations 2c must be larger than in case of smaller wafer diameters, so that wafers W2, in case they slightly tilt, do not contact each other.

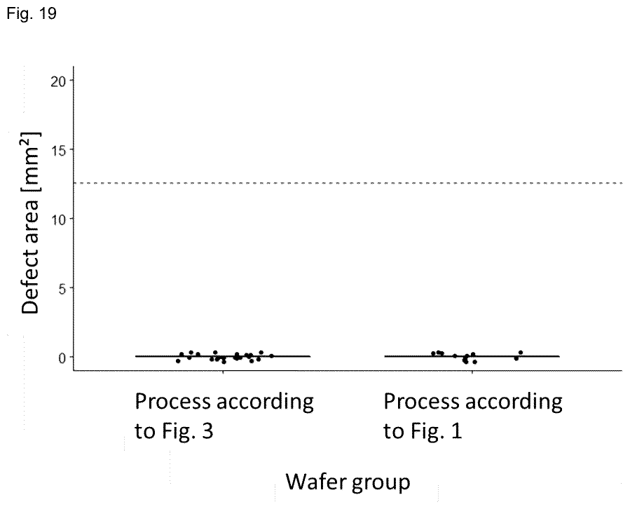

FIG. 18 shows a side view of the wedges 2 of a device according to the present invention. Here, in the left view, the structure of a first wedge section 2a and a second wedge section 2b is shown. In the central view, it is shown here that a wafer with a small diameter W1 (e.g., a 3 inch- or a 150 mm-wafer) is being lifted upward with the first wedge section 2a. In the right view, it is shown that a larger wafer with a larger diameter W2 (e.g., a 200 mm-wafer) is lifted upward with the help of the second wedge section.

FIG. 19 shows a result of a measurement of the defect areas of two corresponding wafer groups of semi-isolating, Fe-doped InP wafers with a diameter of 150 mm; on the right, of wafers that were dried using a conventional Marangoni drying (according to FIG. 1) and, on the left, of wafers that were dried using an improved Marangoni drying according to the present invention (FIG. 3). For the Fe-doped wafers, it could be shown that the spread of different defect areas for wafers produced according to the existing and the new method is similarly small and barely any defect area is visible.

The defect area corresponds to the area that has been measured by the surface measurement using the Candela ellipsometry.

A method for drying of a wafer according to the invention contains a bath with an arrangement of at least one wedge and at least one rack. A rack exhibits the following.

A pair of first lateral guiding devices 3a, 3a′, a pair of second lateral guiding devices 3b, 3b′ as well as a pair of third lateral guiding devices 3c, 3c′.

The pair of first lateral guiding devices 3a, 3a′ is arranged below the pair of second lateral guiding devices 3b, 3b′, and the pair of second lateral guiding devices 3b, 3b′ is arranged below the pair of third lateral guiding devices 3c, 3c′.

The distance between the pair of first lateral guiding devices 3a, 3a′ from each other is preferably smaller than the distance of the pair of second lateral guiding devices 3b, 3b′ from each other, and the distance between the pair of second lateral guiding devices 3b, 3b′ from each other is preferably smaller than the distance of the pair of third lateral guiding devices 3c, 3c′ from each other.

The method according to the invention comprises the following steps:
i) Vertical upward movement of the at least one wedge 2 until contacting the wafer at its lowest point, vertical upward movement of the pair of first lateral guiding devices 3a, 3a′ and the pair of second lateral guiding devices 3b, 3b′, wherein the wafer W contacts the pair of first lateral guiding devices 3a, 3a′ and the pair of second lateral guiding devices 3b, 3b′, wherein an upper area of the wafer W is lifted out of the bath 1, wherein the pair of third lateral guiding devices 3c, 3c′ is not contacting the wafer;
ii) Vertical upward movement of the wedge 2 until the pair of first lateral guiding devices 3a, 3a′ and the pair of second lateral guiding devices 3b, 3b′ are no longer contacting the wafer W, while still being below the liquid surface of the bath 1, wherein the pair of third lateral guiding devices 3c, 3c′ is contacting the wafer above the liquid surface of the bath 1;
iii) Lifting of the wafer W above the liquid level of the bath 1, wherein the pair of third lateral guiding devices 3c, 3c′ is contacting the wafer W.

Compared with the state-of-the-art (see FIG. 1), the holding of the wafers does no longer occur through the fixed holding devices H and H′ that are restricted to a diameter of the wafer (for example, thus inside the lid of the dryer) but rather through the pair of third lateral guiding devices 3c, 3c′, in particular.

Hence, a contact of the wafers with, in particular, the first and second lateral guiding devices 3a, 3a′, 3b, 3b′ of the rack 3, 31, 32 is prevented when the water level accordingly passes said first and second lateral guiding devices. The wafers W, W1, W2 are being held by the third lateral guiding devices 3c, 3c′ that are located above the water level and have already dried. The vertical movement path of the wafers during the drying according to the invention is significantly shorter and may be shortened to a few seconds.

Therefore, droplets, that may form upon contact of wafer and wedge 2, 2a, 2b, occur significantly less frequently and are also smaller. In a Candela measurement of dried wafers according to this method, less and smaller residual droplets are found.

Preferably, the method according to the invention also includes the following steps:
iv) Vertical downward movement of a wedge 2 until the wafer W contacts at least one of the pair of first lateral guiding devices 3a, 3a′ and of the pair of second lateral guiding devices 3b, 3b′;
v) Further vertical downward movement of a wedge 2, until it no longer contacts the wafer W;
while in parallel to the step(s) iv) and/or v) or after the step v) the liquid level of the bath 1 is lowered, until the liquid level is below the wedge 2.

Accordingly, the lateral guiding devices 3a, 3a′, 3b, 3b′ or the rack 3, 31, 32 and the wedge 2, 2a, 2b may be dried, until they are ready for a follow-up drying operation of wafers.

Preferably, the bath 1 contains water and at least one additional surface tension-reducing substance, preferably isopropanol.

It can thus be achieved that the Marangoni effect is optimally utilized in the method according to the invention.

Preferably, the pair of first lateral guiding devices 3a, 3a′, the pair of second lateral guiding devices 3b, 3b′ and/or the pair of third lateral guiding devices 3c, 3c′ each consist of a pair of webs that are arranged in a way to contact opposing sides of the wafer W, W1, W2 at different process steps.

It can thus be ensured that the wafers W, W1, W2 are being held from the side, and do not contact each other during the drying process (i.e., they cannot tip over in the dryer either). Wafers that are contacting each other during the drying may “stick” together and, thereby, prevent drying (i.e., the wafers would then stay wet).

Preferably, the pair of first lateral guiding devices 3a, 3a′ as well as the pair of second lateral guiding devices 3b, 3b′ are submerged in the bath 1 in step i), and, preferably, the pair of third lateral guiding devices 3c, 3c′ does not contact the wafer W, W1, W2 in the end of step v).

As there is only the contact between wedge and wafer at most (or even no contact of the wafer to any guiding device or to the wedge at all) while passing through the liquid surface of the bath, it can be ensured that there are no droplets adhering to the wafer W, W1, W2 in the area of the first, second and third guiding devices, which could reduce the surface homogeneity of the wafer surface accordingly.

Preferably, the wedge 2, 2a, 2b is provided with at least one suction device 6, at which a vacuum is applicable, when the upper tip of the wedge 2, 2a, 2b is located above the liquid level. Hence, it can be ensured that the remaining water at the tips of the wedge 2, 2a, 2b is suctioned, so that the droplet does not reach the wafer W, W1, W2 and might thus cause an inhomogeneity of the oxide surface, accordingly.

Preferably, the wedge 2, 2a, 2b shows a surface tension-increasing surface structure, for example, through a plasma treatment of PEEK, out of which a wedge 2, 2a, 2b may be manufactured. An increased surface tension of the wedge 2, 2a, 2b may lead to that the residual droplet remains at the wedge 2, 2a, 2b and does not spread to the wafer W, W1, W2.

Preferably, the lifting speed depends on the position of the lowest point of the wafer and amounts to between 0.8 and 1.2 mm/s, if the lowest point of the wafer is more than 1.2 cm below the liquid level, and between 0.4 and 0.5 mm/s, if the lowest point of the wafer is less than 1.2 cm below the liquid level, which results in a significant reduction of contact droplets. As too strong fluctuations of the water level may be depicted in the chemical composition of the oxide layer, this speed reduction should occur step by step. The lifting speed is at least 30 mm/s (preferably 40 mm/s or 50 mm/s), as soon as the lowest point of the wafer W has reached the water level. Thereby, it can be prevented that, on the one hand, water from the water level and, on the other hand, residual moisture from the wedge will be drawn again onto the surface of the wafer. Concomitantly, the wedge can be separated from the lower edge of the wafer in the opposite direction.

According to an embodiment, the pair of first lateral guiding devices 3a, 3a′, the pair of second lateral guiding devices 3b, 3b′ as well as the pair of third lateral guiding devices 3c, 3c′ are provided on a rack 3 and, in step i), the entire rack 3 is moved; in step iii), the wafer W is lifted beyond the liquid level of the bath 1, whereby the pair of third lateral guiding devices 3c, 3c′ (already above the liquid level) and the wedge 2 are contacting the wafer W. While passing through the liquid surface, there is only one contact point between wedge and wafer-the droplet area can be minimized.

According to another embodiment, the pair of third lateral guiding devices 3c, 3c′ remains positioned above the liquid level in all process steps, and movable independent of the pair of first lateral guiding devices 3a, 3a′ and the pair of second lateral guiding devices 3b, 3b′, and the third lateral guiding devices 3c, 3c′ are horizontally movable relative to each other. Hence, the third lateral guiding devices 3c, 3c′ remain always dry and can grip the wafer W above the liquid level. While passing through the liquid level, there is no contact point between wedge and wafer at all, accordingly-the droplet area can then even be completely avoided. Preferably, the wedge 2 then remains below the liquid level in all process steps. This is the reason why there is no remaining residual droplet at the wafer in the area of the wedge.

Preferably, the distance between the points at which the third lateral guiding devices 3c, 3c′ are contacting the wafer, is continuously reduced in step iii). Thereby, the wafer W can be vertically moved through horizontal movement of the third lateral guiding devices 3c, 3c′. The third lateral guiding devices 3c, 3c′ are more preferably arranged in a way to carry out a horizontal movement relative to each other.

More preferably, the third lateral guiding devices 3c, 3c′ are eccentrically mounted or show an oval shape and are arranged in a way to carry out a rotary motion. Thereby, a vertical movement of the wafer can be caused by rotary motion of the third lateral guiding devices 3c, 3c′, and may be helpful in the area, in which the last piece of the wafer is lifted out of the bath in this moment, the wedge 2 is not required for the vertical movement of the wafer, through which a contact point wafer W-wedge 2 can be avoided while passing through the liquid surface.

Further process parameters may have an impact on the homogeneity of the oxide surface of a III-V wafer:
As an additional parameter that needs to be controlled for the residual droplet-less Marangoni drying, the concentration of the substance reducing the surface tension of the ultrapure water, preferably isopropyl alcohol (IPA), has emerged. A decline in supply of IPA in the last stage of the drying leads to a larger vertical gradient in surface tension and causes a reduced risk of residual droplet formation. Due to the delayed effect of a reduction in supply of IPA on the concentration of IPA in the gas phase and, subsequently, on the magnitude of the concentration gradient, it can be meaningful to reduce the supply of IPA step by step after the interphase boundary (liquid surface) has passed the center of the wafer. A more pronounced reduction in supply of IPA can be meaningful for n-doped GaAs, in particular.
The gradient of IPA at the interface results from an interplay of the adjusted supply of IPA and the counteracting overflow with deionized water (ultrapure water) in the process bath. Simultaneously, the strength of the overflow has an influence on the particles remaining adhered to the wafers. Wafers made of InP show a higher surface tension (with the same pretreatment) and a significantly higher adhesion ability for particles than GaAs. For a smaller level of residual particles, an overflow of ultrapure water of, e.g., at least 0.1 l/h/cm² (0.1 liters of ultrapure water per hour per cm² liquid surface area in the bath) is required. For reasons of sufficient concentration of IPA at the interface, the overflow is allowed to exceed this value only slightly. Concomitantly, the IPA/N₂ flow needs to be increased by 0,003 to 0,007 l/h/cm² compared to GaAs to compensate for the larger IPA extraction by the overflow-so that the concentration of IPA remains stable at the interface.

Beside the technical and chemical influencing factors of the Marangoni drying itself, the treatment of the III-V semiconductor wafers in the process baths prior to the drying has an influence on the quality of the Marangoni drying and the magnitude of the residual droplets occurring at the contact points at the wedge that is used for lifting. Depending on the cleaning sequence, the final cleaning step may be composed of an acid, an alkaline, or a neutral solution (e.g., by a non-ionic surfactant). The pH value of the final chemical cleaning step prior to the Marangoni drying determines the surface tension of the wafer surface in the drying process. For the optimization of the drying, the concentration of IPA may be adjusted to the surface tension of the wafers to be dried. In this context, hydrophobic wafers need less isopropanol than hydrophilic wafers (e.g., hydrophobic: <0.01 l/h/cm²IPA/N₂, hydrophilic: e.g., >0.01 l/h/cm²IPA/N₂).

An adjustment of the surface tension of the wafers to be dried may, for example, be achieved by the addition of small amounts of acidic or basic additives.

A wafer according to the invention has an oxide layer on at least one surface. Said surface has a defect area of less than 25 mm² in the oxide layer. The wafer is semi-insulating or semiconducting. The surface with the oxide layer is also referred to as oxide surface.

For semi-insulating wafers, even lower defect areas are possible: Here, the defect area is preferably below 15 mm², more preferably below 10 mm², and even more preferably below 5 mm². More preferably, such a wafer is composed of preferably GaAs or InP, even more preferably of undoped or carbon-doped GaAs or iron-doped InP.

Semiconducting wafers may be GaAs wafers and contain silicon as dopant, or an InP wafer and contain sulfur as dopant.

Preferably, the defect area is a continuous area, as exemplarily shown in FIG. 12. Here, at least a part of the defect area may contact the edge of the wafer.

Preferably, at least a part of the defect area is at maximum 5 mm away from the edge of the wafer.

More preferably, at least a part of the defect area is located within a circular ring between the edge of the wafer and a virtual circular line that is a maximum of 10 mm away from the edge of the wafer.

Also preferably, the entire defect area is located within a circular ring between the edge of the wafer and a virtual circular line that is a maximum of 10.5 mm away from the edge of the wafer.

Even more preferably, the entire defect area is located within a circular ring between the edge of the wafer and a virtual circular line that is a maximum of 10 mm away from the edge of the wafer.

Optionally, the wafer has a straight ground section or a notch at a part of the edge, and the defect area is located opposite the straight ground section or the notch.

Corresponding wafers can be produced using the method according to the invention as droplets can be minimized during the drying, which settles in a particularly low defect area.

A device according to the invention for the drying of wafers comprises:
a bath 1 with liquid,
a wedge 2,
at least one bearing device 5, that is vertically movable,
where at least one rack 3; 31, 32 can be mounted into the bearing device 5,
which comprises at least one rack 3; 31, 32:
a pair of first lateral guiding devices 3a, 3a′, a pair of second lateral guiding devices 3b, 3b′ and a pair of third lateral guiding devices 3c, 3c′,
where the pair of first lateral guiding devices 3a, 3a′ is arranged below the pair of second lateral guiding devices 3b, 3b′, and the pair of second lateral guiding devices 3b, 3b′ is arranged below the pair of third lateral guiding devices 3c, 3c′, and where the distance between the pair of first lateral guiding devices 3a, 3a′ from each other is smaller than the distance between the pair of second lateral guiding devices 3b, 3b′ from each other, and the distance between the pair of second lateral guiding devices 3b, 3b′ from each other is smaller than the distance between the pair of third lateral guiding devices 3c, 3c′ from each other,
where the wedge 2 is arranged below the rack 3 and vertically movable separately from the bearing device 5,
where the wedge 2 comprises at least two wedge sections 2a, 2b, where both wedge sections 2a, 2b are vertically movable separated from each other,
where at least a first rack 31 is suspendable in the bearing device 5 in a way that the center of the at least first rack 31 is positioned above the tip of the first wedge section 2a, and further, a second rack 32 is suspendable in a way that the center of the second rack 32 is positioned above the tip of the second wedge section 2b.

The two additional lateral guiding devices (third lateral guiding devices 3c, 3c′) compared to the prior art lead to the fact that these can hold the wafer W, W1, W2 from the side already at the point when they have risen above the liquid surface, and hence, when the wafer W, W1, W2 has passed the liquid surface, a holding can be achieved by the third lateral guiding devices 3c, 3c′ (above the liquid surface) as well as by the wedge 2, 2a, 2b (below the liquid surface). The first lateral guiding devices 3a, 3a′ and the second lateral guiding devices 3b, 3b′ do not contact the wafer W, W1, W2 below the liquid surface and also do not contact it while passing through the liquid surface, which is why a risk of droplet formation in these areas is averted.

In the device according to the present invention, an individual wedge section (2a for smaller wafers W1, 2b for larger wafers W2) with an appropriately suitable length and an appropriately adjusted distance of the elevations 2 c is used for smaller wafers (e.g., diameter of 150 mm or less) and for larger wafers (e.g. diameter of 200 mm or more) each. As the 200 mm-wafers have a larger diameter, the distance of the elevations 2c must be larger than in case of smaller wafer diameters, so that wafers W2, in case they slightly tilt, do not contact each other.

Such a device is suitable for the drying of wafers of multiple diameters, without additional construction effort.

### Examples

GaAs wafers were cleaned using a wet-chemical cleaning procedure—all wafers were double-sided pre-polished and single-sided final polished.

The pre-cleaning was carried out using NH₃ and HCI.

The final cleaning was carried out using a method according to WO 2014/124980A2 : The wafers were subjected to an alkaline cleaning (diluted NH₃ solution plus megasonic), rinsed with deionized water and subsequently dried using the Marangoni drying.

### Example 1

Semi-insulating, undoped GaAs wafers with a diameter of 150 mm were cleaned in a bath and subsequently dried using the Marangoni drying. The undoped wafers were produced from crystals grown via the VGF process and had a specific resistance of 1×10⁸ to 8×10⁸ Ωcm.

48 GaAs wafers were dried using a method of the invention according to FIG. 3. The process speed of the wafers mostly was 1 mm/s (variations are possible for individual phases of the lifting, see above as well as claim 8). With “process speed” it is referred to the speed of the wafers with respect to the water surface.

### Comparative Example 1

Semi-insulating, undoped GaAs wafers with a diameter of 150 mm were cleaned in a bath and subsequently dried using the Marangoni drying. The undoped wafers were produced from crystals grown via the VGF process and had a specific resistance of 1×10⁸ to 8×10⁸ Ωcm.

46 GaAs wafers were dried using a method according to FIG. 1 (state-of-the-art). The process speed of the wafers mostly was 1 mm/s (variations are possible for individual phases of the lifting, see above as well as claim 8).

The comparison of Example 1 and the Comparative Example 1 is shown in FIG. 14.

### Example 2

Silicon-doped GaAs wafers (semiconducting) with a diameter of 150 mm were cleaned in a bath and subsequently dried using the Marangoni drying. The doped wafers were produced from crystals grown via the VGF process and had a Si-doping with a charge carrier concentration of 1×10¹⁸ to 3×10¹⁸ cm⁻³.

84 silicon-doped GaAs wafers were dried using a method of the invention according to FIG. 3. The process speed of the wafers mostly was 1 mm/s (variations are possible for individual phases of the lifting, see above as well as claim 8).

### Comparative Example 2

Silicon-doped GaAs wafers (semiconducting) with a diameter of 150 mm were cleaned in a bath and subsequently dried using the Marangoni drying.

88 silicon-doped GaAs wafers were dried using a method according to FIG. 1 (state-of-the-art). The process speed of the wafers mostly was 1 mm/s (variations are possible for individual phases of the lifting, see above as well as claim 8).

The comparison of Example 2 and the Comparative Example 2 is shown in FIG. 15.

### Example 3

Sulfur-doped InP wafers (semiconducting) with a diameter of 100 mm were cleaned in a bath and subsequently dried using the Marangoni drying.

The sulfur-doped wafers were produced from crystals grown via the VGF process and had a sulfur-doping with a charge carrier concentration of 1.5×10¹⁸ to 9×10¹⁸ cm⁻³.

19 sulfur-doped InP wafers were dried using a method of the invention according to FIG. 3. The process speed of the wafers mostly was 1 mm/s (variations are possible for individual phases of the lifting, see above as well as claim 8).

### Comparative Example 3

Sulfur-doped InP wafers (semiconducting) with a diameter of 100 mm were cleaned in a bath and subsequently dried using the Marangoni drying.

The sulfur-doped wafers were produced from crystals grown via the VGF process and had a sulfur-doping with a charge carrier concentration of 1.5×10¹⁸ to 9×10¹⁸ cm⁻³.

29 InP wafers were dried using a method according to FIG. 1 (state-of-the-art). The process speed of the wafers mostly was 1 mm/s (variations are possible for individual phases of the lifting, see above as well as claim 8).

The comparison of Example 3 and the Comparative Example 3 is shown in FIG. 16.

### Example 4

Fe-doped InP wafers (semi-insulating) with a diameter of 150 mm were cleaned in a bath and subsequently dried using the Marangoni drying. The Fe-doped wafers were produced from crystals grown via the VGF process and had an iron-doping with a charge carrier concentration of 2.8×10⁷ to 3.8×10⁷ cm⁻³. The specific resistance was 4.9×10⁷ to 8.7×10⁷ Ωcm. The dislocation density was 290 to 480 cm⁻².

23 InP wafers were dried using a method of the invention according to FIG. 3. The process speed of the wafers mostly was 1 mm/s (variations are possible for individual phases of the lifting, see above as well as claim 8).

### Comparative Example 4

Fe-doped InP wafers (semi-insulating) with a diameter of 150 mm were cleaned in a bath and subsequently dried using the Marangoni drying. The Fe-doped wafers were produced from crystals grown via the VGF process and had an iron-doping with a charge carrier concentration of 2.8×10⁷ to 3.8×10⁷ cm⁻³. The specific resistance was 4.9×10⁷ to 8.7×10⁷ Ωcm. The dislocation density was 290 to 480 cm⁻².

12 InP wafers were dried using a method according to FIG. 1 (state-of-the-art). The process speed of the wafers mostly was 1 mm/s (variations are possible for individual phases of the lifting, see above as well as claim 8).

The comparison of Example 4 and the Comparative Example 4 is shown in FIG. 19.

Surface characterization of the wafers:

The surface properties of the wafers (oxide surface characteristics on the wafer) are characterized by an optical surface analyzer (Candela ellipsometer) after the drying. For the characterization of the homogeneity of the surface properties, a mapping of the measurement channel QAbsPhase of the Candela CS20 by the company KLA is evaluated. The radial resolution of the Candela measurement is 50 μm, the azimuthal resolution is <30 μm.

The mappings show bright and dark areas as well as stripe structures which can be attributed to inhomogeneities or, in general, to “defects”. The intensity and the number of deviations from the background characterize the homogeneity of a surface. In the evaluation of the droplet size, the contrasts are not derived from threshold values but rather visually based on their extent or, respectively, by a trained algorithm or, respectively, a neural network (see above); here, the absolute value of the measurement signal is not considered, but only clearly identifiable droplet areas. And this evaluation proceeds outside the Candela ellipsometer.

A border exclusion of a maximum of 0.5 mm is applied. The extension of the found droplets inward is a maximum of about 1 cm, so the area being considered covers a radius range between 65 mm and 74.5 mm for a 150-mm wafer, and a radius range between 40 mm and 49.5 mm for a 100-mm wafer.

### REFERENCE SYMBOL LIST

1 bath
2, 2a, 2b wedge
2c elevation
3 rack
31 first rack
32 second rack
3a, 3a′ first lateral guiding device
3b, 3b′ second lateral guiding device
3c, 3c′ third lateral guiding device
3d, 3d′ head section
4 gripping device
5 bearing device
6 suction device
W wafer
H, H′ holding device

1. Method for drying of a wafer (W) that is located inside a bath (1), by using an arrangement comprising at least one wedge (2) as well as
a pair of first lateral guiding devices (3a, 3a′), a pair of second lateral guiding devices (3b, 3b′) and a pair of third lateral guiding devices (3c, 3c′),
wherein the pair of first lateral guiding devices (3a, 3a′) is arranged below the pair of second lateral guiding devices (3b, 3b′), and the pair of second lateral guiding devices (3b, 3b′) is arranged below the pair of third lateral guiding devices (3c, 3c′), and
wherein the method comprises the following steps:
i) Vertical upward movement of at least one wedge (2) until contacting the wafer at its lowest point, vertical upward movement of the pair of first lateral guiding devices (3a, 3a′) and the pair of second lateral guiding devices (3b, 3b′), wherein the wafer (W) contacts the pair of first lateral guiding devices (3a, 3a′) and the pair of second lateral guiding devices (3b, 3b′), wherein an upper area of the wafer (W) is lifted out of the bath (1), wherein the pair of third lateral guiding devices (3c, 3c′) is not contacting the wafer;
ii) Vertical upward movement of the wedge (2) until the pair of first lateral guiding devices (3a, 3a′) and the pair of second lateral guiding devices (3b, 3b′) are no longer contacting the wafer (W), while still being below the liquid surface of the bath (1), wherein the pair of third lateral guiding devices (3c, 3c′) is contacting the wafer above the liquid surface of the bath (1);
iii) Lifting of the wafer (W) above the liquid level of the bath (1), wherein the pair of third lateral guiding devices (3c, 3c′) is contacting the wafer (W).

2. Method for drying of a wafer (W) according to claim 1, further comprising the following steps:
iv) Vertical downward movement of a wedge (2) until the wafer (W) contacts at least one of the pair of first lateral guiding devices (3a, 3a′) and of the pair of second lateral guiding devices (3b, 3b′);
v) Further vertical downward movement of a wedge (2), until it no longer contacts the wafer (W);
while in parallel to the step(s) iv) and/or v) or after the step v) the liquid level of the bath (1) is lowered until the liquid level is below the wedge (2).

3. Method according to claim 1, wherein the bath (1) contains water and at least one additional surface tension-reducing substance, preferably isopropanol.

4. Method according to claim 1, wherein the pair of first lateral guiding devices (3a, 3a′) and the pair of second lateral guiding devices (3b, 3b′) and/or the pair of third lateral guiding devices (3c, 3c′) are composed of a pair of webs that are arranged in a way to contact opposing sides of the wafer (W, W1, W2).

5. Method according to claim 2, wherein the pair of first lateral guiding devices (3a, 3a′) and the pair of second lateral guiding devices (3b, 3b′) remain submerged in the bath (1) in step i), and the pair of third lateral guiding devices (3c, 3c′) does preferably not contact the wafer (W, W1, W2) in the end of step v).

6. Method according to claim 1, wherein the wedge (2, 2a, 2b) is provided with suction devices (6), to which a vacuum is applicable when the upper tip of the wedge (2, 2a, 2b) is located above the liquid level.

7. Method according to claim 1, wherein the wedge (2, 2a, 2b) reveals a surface tension-increasing surface structure.

8. Method according to claim 1, wherein the lifting speed depends on the position of the lowest point of the wafer (W), and lies between 0.8 to 1.2 mm/s, when the lowest point of the wafer (W) is more than 1.2 cm below the liquid level, or between 0.4 and 0.5 mm/s, when the lowest point of the wafer (W) is less than 1.2 cm below the liquid level, and at least 30 mm/s, preferably at least 40 mm/s, more preferably at least 50 mm/s, as soon as the lowest point of the wafer (W) has reached the liquid level.

9. Method according to claim 1, wherein the pair of first lateral guiding devices (3a, 3a′), the pair of second lateral guiding devices (3b, 3b′) as well as the pair of third lateral guiding devices (3c, 3c′) are provided on a rack (3), and
the rack (3) is moved in step i), the wafer (W) is lifted out and above the liquid level of the bath (1) in step iii), wherein the pair of third lateral guiding devices (3c, 3c′) and the wedge (2) are contacting the wafer (W).

10. Method according to claim 1, wherein the pair of third lateral guiding devices (3c, 3c′) is positioned above the liquid level in all process steps and independently movable from the pair of first lateral guiding devices (3a, 3a′) and the pair of second lateral guiding devices (3b, 3b′), and the third lateral guiding devices (3c, 3c′) are horizontally movable relative to each other.

11. Method according to claim 10, wherein the wedge (2) remains below the liquid level in all process steps.

12. Method according to claim 10, wherein the distance between the points at which the third lateral guiding devices (3c, 3c′) contact the wafer (W) is continuously reduced in step iii).

13. Method according to claim 10, wherein the third lateral guiding devices (3c, 3c′) are either eccentrically mounted or show an oval shape and are adapted to perform a rotating motion.

14. III-V wafer (W, W1, W2), wherein the oxide surface reveals a defect area of less than 25 mm², and wherein the III-V wafer (W) is semi-insulating or semiconducting.

15. III-V wafer (W, W1, W2) according to claim 14, in which the oxide surface reveals a defect area of less than 15 mm², preferably of less than 10 mm², more preferably of less than 5 mm², where the III-V wafer (W, W1, W2) is semi-insulating and preferably composed of GaAs or InP, more preferably of undoped or carbon-doped GaAs or of iron-doped InP.

16. III-V wafer (W, W1, W2) according to claim 14, wherein the III-V wafer is semiconducting, and wherein the wafer is a GaAs wafer and contains silicon as dopant, or where the III-V wafer is an InP wafer and contains sulfur as dopant.

17. Device for drying of wafers, comprising:
a bath (1) with liquid;
a wedge (2),
at least one bearing device (5), that is vertically movable;
where at least one rack (3; 31, 32) can be mounted into the bearing device (5),
which comprises at least one rack (3; 31, 32):
a pair of first lateral guiding devices (3a, 3a′), a pair of second lateral guiding devices (3b, 3b′) as well as a pair of third lateral guiding devices (3c, 3c′),
where the pair of first lateral guiding devices (3a, 3a′) is arranged below the pair of second lateral guiding devices (3b, 3b′), and the pair of second lateral guiding devices (3b, 3b′) is arranged below the pair of third lateral guiding devices (3c, 3c′), and
where the distance between the pair of first lateral guiding devices (3a, 3a′) from each other is smaller than the distance between the pair of second lateral guiding devices (3b, 3b′) from each other, and the distance between the pair of second lateral guiding devices (3b, 3b′) from each other is smaller than the distance between the pair of third lateral guiding devices (3c, 3c′) from each other,
where the wedge (2) is provided below the rack (3) and vertically movable separately from the bearing device (5),
wherein the wedge (2) comprises at least two wedge parts (2a, 2b), where both wedge parts (2a, 2b) are vertically movable independent from each other,
where at least a first rack (31) is suspendable in the bearing device (5) in a way that the center of at least the first rack (31) is positioned above the tip of the first wedge section (2a), and further, a second rack (32) is suspendable in a way that the center of the second rack (32) is positioned above the tip of the second wedge section (2b).
